(19) United States
(12) Patent Application Publication
(10) Pub. No.: US 2021/0242394 A1
(43) Pub. Date: Aug. 5, 2021

(54) MAGNETOELECTRIC HETEROSTRUCTURES AND RELATED ARTICLES, SYSTEMS, AND METHODS

(71) Applicants: Massachusetts Institute of Technology, Cambridge, MA (US); Wisconsin Alumni Research Foundation, Madison, WI (US)

(72) Inventors: Jeehwan Kim, Cambridge, MA (US); Hyunseong Kum, Cambridge, MA (US); Chang-beom Eom, Madison, WI (US); Hyungwoo Lee, Suwon-si (KR); Shane Lindemann, Madison, WI (US)

(73) Assignees: Massachusetts Institute of Technology, Cambridge, MA (US); Wisconsin Alumni Research Foundation, Madison, WI (US)

(21) Appl. No.: 17/111,623

(22) Filed: Dec. 4, 2020

Related U.S. Application Data
(60) Provisional application No. 62/970,033, filed on Feb. 4, 2020.

(51) Int. Cl. H01L 41/12; H01L 41/083; H01L 41/47; C30B 29/16

(52) U.S. Cl. CPC H01L 41/12; C30B 29/16; H01L 41/47; H01L 41/083

(57) ABSTRACT

Magnetoelectric heterostructures, and related articles, systems, and methods, are generally described.

### RELATED APPLICATIONS

This application claims priority under 35 U.S.C. 119(e) to U.S. Provisional Patent Application No. 62/970,033, filed Feb. 4, 2020, and entitled “Magnetoelectric Heterostructures and Related Articles, Systems, and Methods,” which is incorporated herein by reference in its entirety for all purposes.

### STATEMENT REGARDING FEDERALLY SPONSORED RESEARCH

This invention was made with Government support under Grant No. HR00111720061 awarded by the Defense Advanced Research Projects Agency (DARPA), and under Grant No. W911NF-17-1-0462 awarded by the Army Research Office. The Government has certain rights in this invention.

### TECHNICAL FIELD

Magnetoelectric heterostructures, and related articles, systems, and methods, are generally described.

### SUMMARY

Magnetoelectric heterostructures, and related articles, systems, and methods are generally described. The subject matter of the present invention involves, in some cases, interrelated products, alternative solutions to a particular problem, and/or a plurality of different uses of one or more systems and/or articles.

Certain aspects are related to piezoelectric layers. In some embodiments, a single crystalline, freestanding, piezoelectric layer having a thickness of less than 100 micrometers is provided.

Some aspects are related to magnetostrictive layers. In certain embodiments, a single crystalline, freestanding, magnetostrictive layer having a thickness of less than 100 micrometers is provided.

Certain aspects are related to multi-layer stacks. In some embodiments, the multi-layer stack comprises an optional substrate; a piezoelectric layer; and a magnetostrictive layer, wherein: the thickness of the multi-layer stack, including the optional substrate when present, is less than 1 millimeter, and the distance between the piezoelectric layer and the magnetostrictive layer, as measured through the thickness of the multi-layer stack, is less than 100 micrometers.

Some aspects are related to methods. In certain embodiments, the method comprises forming a single crystalline layer directly on a single crystalline growth substrate and separating the single crystalline layer from the single crystalline growth substrate, wherein the lattice mismatch between the single crystalline growth substrate and the single crystalline layer is at least 2%.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention.

FIG. 1 is a perspective view schematic illustration of a freestanding piezoelectric layer, according to certain embodiments.

FIG. 2 is a perspective view schematic illustration of a freestanding magnetostrictive layer, according to certain embodiments.

FIGS. 3A-3G are a series of cross-sectional schematic illustrations showing methods of forming freestanding layers, according to certain embodiments.

FIGS. 4A-4B are cross-sectional schematic illustrations of multi-layer stacks, according to certain embodiments.

FIGS. 5A-5K are related to epitaxial lift-off of complex-oxide membranes on graphene-coated substrates. FIGS. 5A-5K include the following: Cross-sectional TEM of STO film grown on a graphene-coated STO substrate (FIG. 5A), without, and (FIG. 5B), with a graphene protection layer. White boxes indicate the FFT areas to confirm the crystallinity of each epitaxial region in comparison to the substrate. (FIG. 5C), EBSD of the exfoliated STO membrane, confirming single-crystalline out-of-plane (001) orientation. (FIG. 5D), Asymmetric ϕ scan of the STO membrane measured by HRXRD. EBSD and asymmetric ϕ scans of (FIGS. 5E-5F), CFO (100) and (FIGS. 5G-5H), YIG (111) membranes, showing single crystallinity with uniform out-of-plane orientation and no in-plane rotation. (FIGS. 5I-5K), Picture of the exfoliated oxide membranes (100 nm of STO, CFO, and YIG, respectively) supported on thermal release tape. The strain applied to the film in the figure with a bending radius of 1.5 cm was not sufficient to crack the films. The strain increased with thickness and for the 100 nm-thick films with 1.5 cm bending radius, the strain was around 0.1% which was much smaller than critical cracking strain of ˜1%.

FIGS. 6A-6F are related to precise epitaxial interface separation of PMN-PT on a SRO/STO substrate. FIGS. 6A-6F include the following: (FIG. 6A), Photograph of as-grown PMN-PT on a SRO/STO substrate (left), SRO/STO substrate after PMN-PT exfoliation (bottom right), and exfoliated PMN-PT membrane (top right). The scale bar indicates 2 mm. (FIG. 6B), HAADF-STEM image of the PMN-PT/SRO/STO interface, with high-stress Ni (100 nm) deposited on top. (FIG. 6C), AFM of the SRO/STO substrate surface after exfoliating the PMN-PT. The scale bar indicates 5 micrometers. (FIG. 6D), Cross-sectional TEM of the exfoliated PMN-PT using a Ti (30 nm)/Ni (3 micrometers) metal stressor layer, verifying the integrity of the PMN-PT crystallinity after exfoliation. Needle-like contrast areas are due to slight variations in composition and phase caused by misfit strain. Representative HRTEM and selective-area diffraction is also shown, verifying the single crystalline nature of the exfoliated PMN-PT membrane. (FIG. 6E), EBSD and (FIG. 6F), asymmetric ϕ scan of the exfoliated PMN-PT membrane, showing high quality single-crystallinity and no in-plane rotation.

FIGS. 7A-7E are related to heterogeneous integration of CFO and PMN-PT membranes for strain-mediated thin-film magnetoelectrically coupled heterostructure. FIGS. 7A-7E include the following: (FIG. 7A), Schematic of the CFO/PMN-PT ME device. The CFO has an area of 4×3 mm² and a thickness of 300 nm. The PMN-PT has an area of 5×5 mm² and a thickness of 400 nm. For the clamped device, the substrate is STO and the bottom electrode is SRO. For the freestanding membrane device, the substrate is PDMS and the bottom electrode is Ti. (FIG. 7B), Schematic of the setup to measure the magnetic-field induced voltage across the PMN-PT. A small ac magnetic field is supplied by a Helmholtz coil and a dc magnetic field is provided by an electromagnet. The magnetic field direction is applied parallel to the sample. The voltage generated across the PMN-PT membrane is measured as a function of the ac magnetic field amplitude with a lock-in amplifier. DUT stands for device under test. (FIG. 7C), The voltage induced across the PMN-PT (δV_{ME}) as a function of the ac magnetic field strength at a frequency of 1 kHz. The inset shows a schematic of the freestanding vs. clamped device. (FIG. 7D), Cross-sectional TEM image of the CFO/PMN-PT membrane heterostructure. A thin Pt (7 nm) film was deposited before transferring the CFO as the top contact to PMN-PT. The box shows a zoomed-in TEM of the CFO/Pt/PMN-PT interface, showing that an oxide bonding layer has formed spontaneously. (FIG. 7E), In-situ TEM of CFO as a function of applied voltage across the PMN-PT membrane. The strain generated by applying a voltage across the PMN-PT is transferred to the CFO layer, which induces a large change in strain contrast. The movement of the strain contrast can be more clearly seen in video form.

FIGS. 8A-8H are related to electrical, magnetostatic, and magnetoelastic coupling between 3D and 2D materials. FIGS. 8A-8H include the following: (FIG. 8A), Out-of-plane magnetic hysteresis of CFO membrane, YIG membrane, and CFO/YIG membrane heterostructure measured at room temperature. The YIG and CFO membranes individually show hysteresis loops with an in-plane easy axis resulting from shape anisotropy, with the YIG having a low in-plane coercivity of H_{c,IP}=10 Oe and the CFO magnetically harder with H_{c,IP}=2950 Oe (see FIGS. 10A-10B), and the out-of-plane loops corresponding to hard-axis loops. (FIG. 8B), The linear sum of the magnetic hysteresis of individual CFO and YIG membranes compared to the measured CFO/YIG membrane heterostructure. (FIG. 8C), Magnetic hysteresis of the CFO/YIG membrane and just the CFO membrane at 300° C. The YIG becomes paramagnetic and only the CFO loop remains at 300° C. When the heterostructure membrane is cooled back down to room temperature, full recovery of the original hysteresis is observed. (FIG. 8D), Schematic illustration of the electrical coupling between graphene and magnetic insulators. Graphene is undoped (the Fermi-level lies at the Dirac point) on thick h-BN, n-doped on YIG, and p-doped on CFO, shifting the Fermi-level back near the Dirac point when sandwiched between YIG and CFO. (FIG. 8E), The Raman spectra (focused on the 2D peak and G peak) of each structure shown in (FIG. 8D). The shift in the (FIG. 8F), 2D peak, (FIG. 8G), G peak, and (FIG. 8H), FWHM of the G peak for graphene on h-BN, YIG, and sandwiched between YIG and CFO membranes, respectively.

FIGS. 9A-9D are related to DFT simulation of substrate surface potential penetrating through graphene layers on a STO substrate. FIGS. 9A-9D include the following: (FIG. 9A), Illustration of the simulated structure. (FIG. 9B), The potential fluctuation through graphene as a function of monolayer and bilayer graphene thickness. The inset shows the potential fluctuation map on the surface of graphene-coated STO substrates for monolayer graphene (left) and bilayer graphene (right). (FIG. 9C), The potential fluctuation map with three monolayers of graphene on top of STO surface. (FIG. 9D), Cross-sectional potential profile along the line shown in FIG. 9C.

FIGS. 10A-10B are related to PLD of STO on graphene-coated STO substrate. FIGS. 10A-10B include the following: (FIG. 10A), RHEED pattern during growth of STO on graphene-coated STO substrate, showing crystalline growth through the entire growth process. The embedded arrows indicate RHEED patterns due to the transferred graphene. (FIG. 10B), RHEED oscillation during the growth of STO on graphene-coated STO substrate.

FIGS. 11A-11C are related to cross-sectional TEM analysis of exfoliated STO membrane. FIGS. 11A-11C include the following: (FIG. 11A), Low-magnification TEM image of STO membrane supported by Ni stressor layer. (FIG. 11B), Zoom-in of polycrystalline domains caused by residues left on graphene after transfer. (FIG. 11C), High-resolution TEM image of the STO membrane (center), showing SAED (left) and HR-TEM (right), confirming the overall single-crystallinity of the membrane.

FIGS. 12A-12H are related to STEM analysis of the SrTiO₃ buffer layer grown in vacuum. FIGS. 12A-12H include the following: (FIG. 12A), and (FIG. 12B), show the bright field (BF) and high-angle annular dark-field (HAADF)-STEM images of the exfoliated STO membrane at low magnification, respectively. (FIG. 12C), and (FIG. 12D), show a higher resolution BF and HAADF-STEM, respectively, of the sample. (FIG. 12E), Electron energy loss spectroscopy (EELS) spectra and line profile from the exfoliated surface to the “bulk” region (indicated as A-B in (FIG. 12D)), verifying that the composition of the buffer layer grown in vacuum is identical to the region grown in an oxygen ambient. (FIG. 12F), High resolution HAADF, showing individual atoms of the STO membrane at the exfoliation surface (the region grown in vacuum). The annular bright-field (ABF) and contrast inverted ABF ((FIG. 12G) and (FIG. 12H)) clearly show the absence of oxygen vacancies and no discernible differences are observed between the regions grown in vacuum and in oxygen.

FIGS. 13A-13C are related to cross-sectional TEM analysis of exfoliated CFO membrane. FIGS. 13A-13C include the following: (FIG. 13A), Cross-sectional TEM of exfoliated CFO on the Ti/Ni stressor layer. The dotted line indicates polycrystalline domain caused by residues left during graphene transfer. (FIG. 13Bb), Zoomed-in TEM of the polycrystalline area marked by dotted lines. (FIG. 13C), Higher resolution cross-sectional TEM of the CFO film (center), SAED (left), and HR-TEM (right) conforming overall single-crystallinity of the membrane.

FIGS. 14A-14D are related to exfoliation and characterization of BaTiO₃ membrane grown via MBE. FIGS. 14A-14D include the following: (FIG. 14A), Photograph of exfoliated BTO membrane (50 nm) grown via remote epitaxy. (FIG. 14B), EBSD of the exfoliated BTO membrane show single crystalline (100) orientation. (FIG. 14C), The inverse-pole map of the EBSD data shown in (FIG. 14B). (FIG. 14D), Kikuchi band of the BTO membrane.

FIGS. 15A-15F are related to the reusability of a graphene-coated MAO substrate. FIGS. 15A-15F include the following: Microscope image of a MAO substrate after exfoliating a CFO film grown on (FIG. 15A), monolayer and (FIG. 15B), bilayer graphene, where severe damage on the surface of the MAO substrate after exfoliation of CFO grown on monolayer graphene was observed due to crack propagation into the substrate. No evidence of damage was observed on substrates coated with bilayer graphene since the second graphene transfer covers the macroscopic defective areas of the first graphene layer. The scale bar indicates 1 mm. (FIG. 15C), AFM of the pristine MAO substrate surface (left) and after one cycle of CFO exfoliation (right) with a root mean square (RMS) roughness of approximately 5.5 Å before and after exfoliation. Scale bar indicates 1 micrometer. (FIG. 15D), Raman spectra and (FIG. 15E), Raman intensity mapping of the 2D peak (2685 cm⁻¹) of graphene on MAO substrate after one cycle of CFO exfoliation, showing evidence that graphene is preserved on the MAO substrate after exfoliation, likely due to the non-specific adhesion between graphene and CFO is weaker than that between graphene and MAO. Where this is not the case, one could etch off any graphene remaining on the substrate and re-deposit graphene before epitaxy. The scale bar indicates 10 micrometers. (FIG. 15F), Magnetic hysteresis of the three exfoliated CFO membranes produced on a single graphene-coated MAO substrate measured by VSM at room temperature.

FIGS. 16A-16D are related to STEM imaging and strain analysis of the PMN-PT/SRO/STO interface. FIGS. 16A-16D include the following: (FIG. 16A), and (FIG. 16B), Cross-sectional HAADF-STEM images of PMN-PT/SRO/STO interface without and with a Ni stressor layer, respectively. Clear straining at the PMN-PT/SRO interface can be seen with a Ni stressor layer while the SRO/STO interface remains unstrained. (FIG. 16C), Atomic-resolution STEM image of one of the periodic edge-dislocations observed at the PMN-PT/SRO interface. (FIG. 16D), Geometric phase analysis (GPA) of the PMN-PT/SRO and SRO/STO interface in the x (2nd column), y (3rd column), and rotational geometry (last column) with and without the Ni stressor layer. The white arrows indicate edge-dislocations.

FIGS. 17A-17B are related to a description of the in-situ TEM CFO/PMN-PT heterostructure device. FIGS. 17A-17B include the following: (FIG. 17A), A cross-sectional SEM of the in-situ CFO/PMN-PT ME device. A thick Pt layer (labeled TEM probe contact) was deposited on top of the 7 nm thick Pt layer for the TEM probe tip to establish electrical contact. The TEM probe contact was intentionally made much thicker and far away from the actively observed region (distance greater than 5 μm) to prevent effects from the bending of the sample. (FIG. 17B), HR-TEM image of the CFO/Pt/PMN-PT interface, showing a thin amorphous oxide layer that has formed between the CFO and Pt for efficient strain-coupling.

FIGS. 18A-18B are related to CFO magnetic hysteresis as a function of voltage applied across PMN-PT. FIGS. 18A-18B include the following: CFO magnetism with a varying voltage bias across a PMN-PT measured via VSM. (FIG. 18A), In the clamped structure, the PMN-PT film is grown on a SRO/STO substrate, and the CFO membrane is transferred on top of a thin Pt layer deposited on top of PMN-PT. (FIG. 18B), In the freestanding structure, the PMN-PT membrane is transferred onto a PDMS substrate after exfoliation. The rest of the stack is identical.

FIGS. 19A-19H are a series of images and schematic illustrations showing a process for transferring graphene.

FIGS. 20A-20C are a series of images related to the exfoliation of an STO membrane on graphene-coated STO substrates with varying graphene thickness. FIGS. 20A-20C include the following: (FIG. 20A), monolayer graphene compared to (FIG. 20B), bilayer (monolayer graphene transferred twice) and (FIG. 20C), trilayer graphene (monolayer graphene transferred three times). Holes are evident (indicated by an arrow) and are due to macroscopic holes and tears of the graphene during transfer, resulting in homoepitaxy on those areas and ultimately leading to spalling during exfoliation. The scale bar indicates 20 micrometers.

FIGS. 21A-21C are related to the magnetic hysteresis of CFO and YIG freestanding membrane. FIGS. 21A-21C include the following: (FIG. 21A), and (FIG. 21B), Magnetic hysteresis of CFO and YIG freestanding membranes, respectively. (FIG. 21C), Photographs of a YIG film on a GGG substrate and a YIG membrane on a piece of tape. Magnetization values of freestanding CFO and YIG are within reasonable range from bulk values (200-400 emu/cm³ for CFO and 135 emu/cm³ for YIG), proving good quality of freestanding single-crystalline membranes.

FIGS. 22A-22F are related to undesired spalling during the exfoliation process. FIGS. 22A-22F include the following: (FIGS. 22A-22B), Illustration and photograph image, respectively, of spalling into the substrate during exfoliation when a crack initiates into the substrate at homoepitaxial spots which occurs through damaged graphene. (FIGS. 22C-22D), Illustration and photograph image, respectively, showing crack initiation up into the epitaxial layer during exfoliation, which leaves areas of epitaxial film on the substrate. The epitaxial film can be etched and the substrate can be reused if needed. (FIGS. 22E-22F), Illustration and photograph image, respectively, showing no damage to the substrate or epitaxial film is seen during exfoliation when bilayer graphene is successfully transferred (two transfers of monolayer graphene), which eliminates regions in which homoepitaxy can occur. Scale bar indicates 5 mm.

FIGS. 23A-23E are a series of TEM images of (110) PMN-PT membrane. FIGS. 23A-23E include the following: (FIGS. 23A-23B), Low magnification cross-sectional image of the exfoliated (110) PMN-PT membrane. (FIG. 23C), High-resolution TEM indicating the atomic distances and (FIG. 23D), selective-area diffraction of the same membrane. (FIG. 23E), EBSD of exfoliated PMN-PT (110) membrane.

FIGS. 24A-24F are related to an oxide membrane transfer process. FIGS. 24A-24F include the following: (FIG. 24A), The complex-oxide film is exfoliated from the substrate by depositing a Ni stressor layer and attaching thermal release tape as a handling platform. (FIG. 24B), PMMA A6 is spin coated and baked at 80° C. for 5 minutes. (FIG. 24C), The thermal release tape is released by heating the tape on a hotplate at 110° C. (FIG. 24D), The film is placed on a Ni etchant solution until all Ni is etched. (FIG. 24E), Once all traces of Ni are gone, the film is transferred onto the desired substrate. (FIG. 24F), The PMMA is completely removed by continuously dripping acetone and finally rinsed by dripping IPA.

### DETAILED DESCRIPTION

Magnetoelectric heterostructures, and related articles, systems, and methods are generally described. Certain embodiments are related to freestanding piezoelectric layers and/or freestanding magnetostrictive layers. In accordance with certain embodiments, the ability to make and manipulate such layers can allow for the production of multi-layer stacks that produce a relatively high level of magnetoelectric response while also having relatively small dimensions. In addition, the use of freestanding piezoelectric layers and/or freestanding magnetostrictive layers can allow one to assemble stacks of such layers without using adhesives (e.g., glue) and/or without using large, bulky growth substrates. This can allow one to produce small, lightweight, and/or mechanically flexible multi-layer stacks (e.g., a magnetoelectric device) comprising one or more piezoelectric layers and one or more magnetostrictive layers.

Certain aspects are related to methods of forming freestanding piezoelectric layers and/or freestanding magnetostrictive layers. In some embodiments, single crystalline piezoelectric or magnetostrictive layers are grown on a growth substrate and subsequently removed from the growth substrate such that they are freestanding. In some such embodiments, a two-dimensional material is positioned between the single crystalline material and the growth substrate. In certain embodiments, the presence of the two-dimensional material can facilitative relatively easy removal of the single crystalline material from the growth substrate, for example, due to relatively weak bonding between the growth substrate and the two-dimensional material and/or due to relatively weak bonding between the two-dimensional material and the single crystalline material.

In some embodiments, two layers of the two-dimensional material are used during growth of the single crystalline material. In some such embodiments, a first layer of the two-dimensional material is consumed during the growth of the single crystalline material and a second layer of the two-dimensional material remains in place between the single crystalline material and the growth substrate, facilitating removal of the single crystalline material from the growth substrate.

In still further embodiments, the two-dimensional material is not used during growth of the single crystalline material, and the single crystalline material is grown directly on the growth substrate, after which the single crystalline material is removed (e.g., via the introduction of stress on the growth substrate and/or the single crystalline material, which can result in release of the single crystalline material via propagation of a crack between the single crystalline material and the growth substrate).

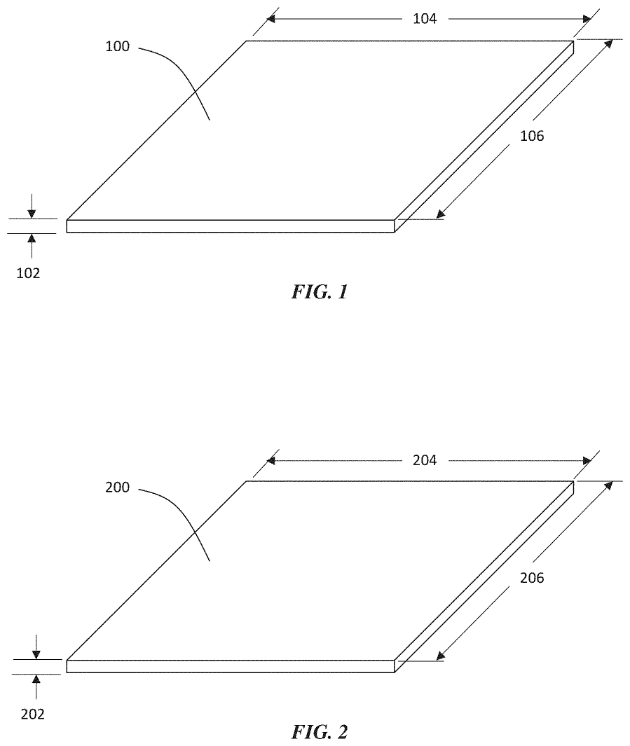

As noted above, certain embodiments are related to freestanding piezoelectric layers. FIG. 1 is a schematic illustration of freestanding piezoelectric layer 100. A layer is considered to be “freestanding,” as that term is used herein, when it is not bound to an adjacent substrate. For example, in FIG. 1, piezoelectric layer 100 is freestanding because it is not bound to an adjacent substrate. It should be noted that a freestanding layer can be in contact with another material (e.g., a substrate) and still be freestanding, as long as the freestanding layer is not bound to the other material. For example, a layer that is in contact with an adjacent substrate and that can be removed from that substrate (e.g., peeled off of or otherwise removed) without damaging the layer and the substrate would still be considered a freestanding layer.

In certain embodiments, the piezoelectric layer is single crystalline. Single crystalline layers are distinguished from polycrystalline layers in that single crystalline layers do not have multiple crystalline domains separated by grain boundaries.

The freestanding piezoelectric layer can be relatively thin, in certain embodiments, as described in more detail below.

Freestanding magnetostrictive layers are also described herein. FIG. 2 is a schematic illustration of freestanding magnetostrictive layer 200. In certain embodiments, the magnetostrictive layer is single crystalline.

The freestanding magnetostrictive layer can be relatively thin, in some embodiments, as described in more detail below.

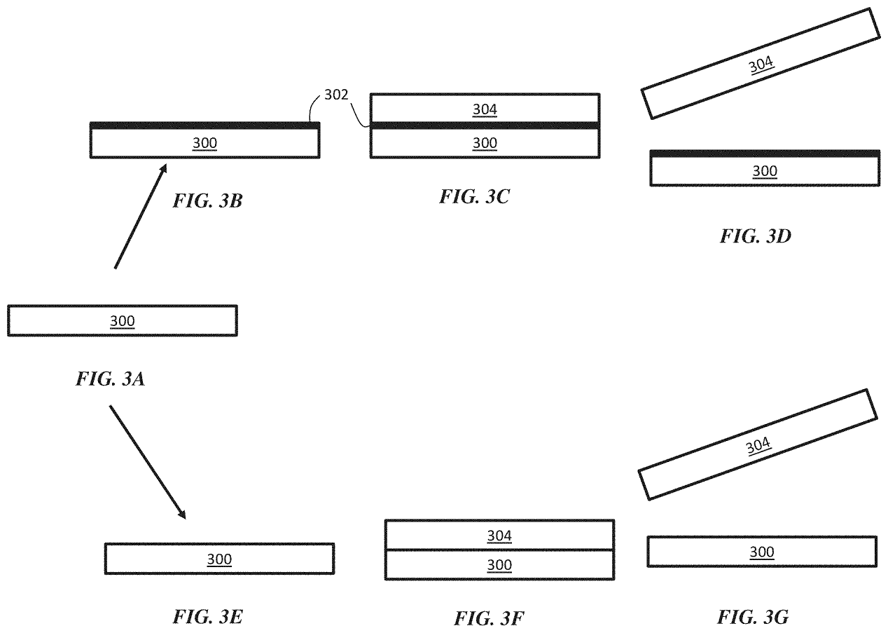

Freestanding piezoelectric layers and freestanding magnetostrictive layers can be produced, for example, by growing them on a growth substrate and subsequently separating the layer and the growth substrate. This process is illustrated, for example, in FIGS. 3A-3G.

Referring to FIG. 3A, growth substrate 300 is provided. In some embodiments, the growth substrate is single crystalline. A variety of growth substrate materials can be used including, but not limited to, SrTiO₃ (STO), MgAl₂O₄ (MAO), Gd₃Ga₅O₁₂ (GGG), SrRuO₃ (SRO), NdGaO₃ (NGO), DyScO₃ (DSO), LaAlO₃ (LAO), NdScO₃ (NSO), BaTiO₃ (BTO), SiO₂, and Si. Other materials may also be possible.

In some embodiments, one or more layers of optional 2-dimensional material are positioned over the growth substrate prior to growth of the single crystalline layer. For example, FIG. 3B shows optional 2-dimensional material 302 over growth substrate 300. In some embodiments, the 2-dimensional material, when present, forms a weak bond with the growth substrate and/or the subsequently grown single crystalline layer, which can facilitate the removal of the single crystalline layer from the growth substrate.

A variety of 2-dimensional materials can be used. In some embodiments, the 2-dimensional material comprises graphene. In certain embodiments, the 2-dimensional material comprises a transition metal dichalcogenide (TMD). Other two-dimensional materials may also be possible.

In certain embodiments, the single crystalline layer (e.g., the piezoelectric layer, the magnetostrictive layer) is grown over the growth substrate (and, when the optional 2-dimensional material is present, over the 2-dimensional material). For example, FIG. 3C shows single crystalline layer 304 formed over growth substrate 300 and 2-dimensional material 302.

In other cases, 2-dimensional material 302 is not present. For example, in FIG. 3E, no 2-dimensional material is positioned over growth substrate 300. Certain embodiments comprise forming the single crystalline layer directly on the growth substrate (e.g., a single crystalline growth substrate). For example, FIG. 3F shows single crystalline layer 304 formed directly on growth substrate 300, with no 2-dimensional material present.

Certain embodiments comprise separating the growth substrate and the single crystalline layer to form a freestanding single crystalline layer (e.g., a freestanding, single crystalline piezoelectric layer; or a freestanding single crystalline magnetostrictive layer). For example, in FIG. 3D, 2-dimensional material 302 facilitates the separation of single crystalline layer 304 and growth substrate 300, such that single crystalline layer 304 becomes a freestanding layer. Similarly, in FIG. 3G, single crystalline layer 304 and growth substrate 300 have been separated (e.g., due to propagation of a crack at the interface between the growth substrate and the single crystalline layer, or by any other suitable mechanism), such that single crystalline layer 304 becomes a freestanding layer.

In some embodiments, the growth substrate is a single crystalline growth substrate, and the single crystalline material that is grown directly on the single crystalline growth substrate can have a relatively high degree of lattice mismatch with the single crystalline substrate. For example, in some embodiments, the lattice mismatch between the single crystalline growth substrate and the single crystalline layer is at least 2% (or at least 4%, at least 6%, at least 8%, or more). In some embodiments, the lattice mismatch between the single crystalline growth substrate and the single crystalline layer is less than 12%, less than 11%, or less than 10%. Without wishing to be bound by any particular theory, it is believed that this level of lattice mismatch can allow one to remove the single crystalline material from the single crystalline substrate without the use of an intermediate 2-dimensional material while also avoiding fracturing, cracking, or otherwise damaging the single crystalline material. In some embodiments, the single crystalline layer has a perovskite crystal structure and the single crystalline growth substrate has a perovskite crystal structure. In certain embodiments, the single crystalline layer has a spinel crystal structure and the single crystalline growth substrate has a spinel crystal structure. In some embodiments, the single crystalline layer has a garnet crystal structure and the single crystalline growth substrate has a garnet crystal structure.

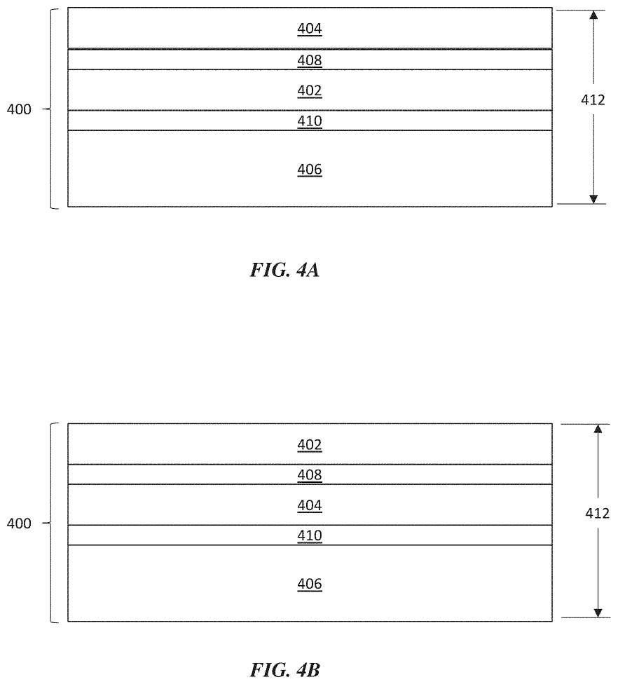

Certain aspects are directed to a multi-layer stack. In some embodiments, the multi-layer stack comprises a piezoelectric layer and a magnetostrictive layer. Optionally, the stack may also comprise a substrate. FIG. 4A is a schematic illustration of multi-layer stack 400, in accordance with certain embodiments. In FIG. 4A, multi-layer stack 400 comprises piezoelectric layer 402 and magnetostrictive layer 404. Piezoelectric layer 402 and/or magnetostrictive layer 404 may be made, for example, using the process outlined in FIGS. 3A-3G, in some embodiments.

As shown in FIG. 4A, multi-layer stack 400 also comprises optional substrate 406. In some embodiments, the piezoelectric layer is between the stack substrate (when present) and the magnetostrictive layer. For example, in FIG. 4A, piezoelectric layer 402 is between substrate 406 and magnetostrictive layer 404. In other embodiments, the magnetostrictive layer is between the stack substrate and piezoelectric layer. For example, in the embodiment illustrated in FIG. 4B, magnetostrictive layer 404 is between substrate 406 and piezoelectric layer 402.

In certain embodiments, the multi-layer stack further comprises optional electrodes. In some embodiments, the multi-layer stack comprises a first electrode between the piezoelectric layer and the magnetostrictive layer. For example, in FIGS. 4A-4B, multi-layer stack 400 further comprises first electrode 408 between piezoelectric layer 402 and magnetostrictive layer 404. The first electrode is generally electronically conductive and can be made from any of a variety of materials (e.g., one or more metals such as platinum (Pt) or gold (Au), one or more electronically conductive polymers, and/or combinations of these and/or other materials).

In some embodiments, the multi-layer stack comprises a second electrode. For example, in FIGS. 4A-4B, multi-layer stack 400 further comprises second electrode 410. The second electrode is generally electronically conductive and can be made from any of a variety of materials (e.g., one or more metals such as Pt or Au, one or more electronically conductive polymers, and/or combinations of these and/or other materials).

In some embodiments, the first electrode is positioned on a first side of the piezoelectric layer, and the second electrode is positioned on a second side of the piezoelectric layer that is opposite the first side of the piezoelectric layer. For example, in FIG. 4A, first electrode 408 is positioned on a first side of piezoelectric layer 402, and second electrode 410 is positioned on a second side of piezoelectric layer 402 that is opposite the first side of piezoelectric layer 402. In some embodiments, the second electrode is positioned between the piezoelectric layer and the stack substrate. For example, in FIG. 4A, second electrode 410 is between piezoelectric layer 402 and substrate 406.

In some embodiments, the first electrode is positioned on a first side of the magnetostrictive layer, and the second electrode is positioned on a second side of the magnetostrictive layer that is opposite the first side of the magnetostrictive layer. For example, in FIG. 4B, first electrode 408 is positioned on a first side of magnetostrictive layer 404, and second electrode 410 is positioned on a second side of magnetostrictive layer 404 that is opposite the first side of magnetostrictive layer 404. In some embodiments, the second electrode is positioned between the magnetostrictive layer and the stack substrate. For example, in FIG. 4B, second electrode 410 is between magnetostrictive layer 404 and substrate 406.

In accordance with certain embodiments, the ability to manipulate freestanding piezoelectric layers and freestanding magnetostrictive layers can allow one to fabricate multi-layer stacks that are relatively thin. In some embodiments, the thickness of the multi-layer stack (shown as dimension 412 in FIGS. 4A and 4B) is less than 1 millimeter, less than 500 micrometers, less than 100 micrometers, less than 10 micrometers, or less.

In some embodiments, the multi-layer stack is a freestanding multi-layer stack. For example, multi-layer stack 400 in FIGS. 4A and 4B are freestanding because there are no substrates that are not part of the multi-layer stack to which the multi-layer stack is bound. (Optional stack substrate 406, when present, forms a part of the multi-layer stack in FIGS. 4A and 4B.)

In certain embodiments, the ability to manipulate freestanding piezoelectric layers and freestanding magnetostrictive layers can allow one to fabricate multi-layer stacks in which the piezoelectric layer and the magnetostrictive layer are relatively close to each other. In some embodiments, the distance between the piezoelectric layer and the magnetostrictive layer, as measured through the thickness of the multi-layer stack, is less than 100 micrometers (or, in some embodiments, less than 10 micrometers, less than 1 micrometer, less than 100 nanometers, less than 100 nanometers, less than 10 nanometers, or less). For example, referring to FIGS. 4A and 4B, the distance between piezoelectric layer 402 and magnetostrictive layer 404 corresponds to the thickness of first electrode 408, which can be very thin (e.g., less than 100 micrometers). Without wishing to be bound by any particular theory, it is believed that positioning the piezoelectric layer and the magnetostrictive layer relatively close together can enhance the magnetoelectric properties of the multi-layer stack.

In some embodiments, the ability to manipulate freestanding piezoelectric layers and freestanding magnetostrictive layers can allow one to fabricate multi-layer stacks that are flexible. In some embodiments, the multi-layer stack has a Young's modulus, as measured by ASTM test E111, of less than 900 GPa, less than 800 GPa, less than 700 GPa, less than 600 GPa, or less.

In some embodiments, the multi-layer stacks described herein are capable of achieving relatively high magnetoelectric coupling coefficients. In some embodiments, the multi-layer stack is capable of achieving a magnetoelectric coupling coefficient of at least 200 mV cm⁻¹ Oe ⁻¹ (or, in some embodiments, at least 500 mV cm⁻¹ Oe ⁻¹, at least 1500 mV cm⁻¹ Oe ⁻¹, or at least 2500 mV cm⁻¹ Oe ⁻¹).

The piezoelectric layer (whether freestanding or part of the multi-layer stack) is generally able to generate an electric charge in response to an applied mechanical stress. In some embodiments, the piezoelectric layer has a piezoelectric coefficient (d₃₃) of greater than or equal to 1000 pC/N, greater than or equal to 2000 pC/N, greater than or equal to 3000 pC/N, greater than or equal to 4000 pC/N, or greater. In some embodiments, the piezoelectric layer has a piezoelectric coefficient (d₃₃) of greater than or equal to 1000 pC/N and less than or equal to 5000 pC/N.

The piezoelectric layer (whether freestanding or part of the multi-layer stack) can have a relatively small thickness, in certain embodiments. For example, referring to FIG. 1, freestanding piezoelectric layer 100 can have a relatively small thickness 102, in some embodiments. Similarly, referring to FIGS. 4A-4B, piezoelectric layer 402 can have a relatively small thickness, in some embodiments. In certain embodiments, the piezoelectric layer (whether freestanding or part of the multi-layer stack) has a thickness of less than 100 micrometers, less than 10 micrometers, less than 1 micrometer, or less.

In some embodiments, the piezoelectric layer (whether freestanding or part of the multi-layer stack) has a thickness as well as two orthogonal lateral dimensions that are orthogonal to each other as well as orthogonal to the thickness. For example, referring to FIG. 1, in accordance with certain embodiments, piezoelectric layer 100 has thickness 102, lateral dimension 104, and a second lateral dimension 106 orthogonal to both thickness 102 and lateral dimension 104. In some embodiments, at least one of the lateral dimensions of the piezoelectric layer (whether freestanding or part of the multi-layer stack) is at least 10 times, at least 100 times, at least 1000 times, at least 10,000 times, at least 100,000 times, or at least 1 million times greater than the thickness of the piezoelectric layer. In some embodiments, both of the lateral dimensions of the piezoelectric layer (whether freestanding or part of the multi-layer stack) are at least 10 times, at least 100 times, at least 1000 times, at least 10,000 times, at least 100,000 times, or at least 1 million times greater than the thickness of the piezoelectric layer.

In some embodiments, the piezoelectric layer (whether freestanding or part of the multi-layer stack) has at least one lateral dimension of at least 1 micrometer, at least 10 micrometers, at least 100 micrometers, at least 1 millimeter, or at least 10 millimeters. In some embodiments, the piezoelectric layer (whether freestanding or part of the multi-layer stack) has a minimum lateral dimension of at least 1 micrometer, at least 10 micrometers, at least 100 micrometers, at least 1 millimeter, or at least 10 millimeters. In some embodiments, the piezoelectric layer (whether freestanding or part of the multi-layer stack) has two lateral dimensions, each orthogonal to each other, of at least 1 micrometer, at least 10 micrometers, at least 100 micrometers, at least 1 millimeter, or at least 10 millimeters.

The piezoelectric layer (whether freestanding or part of the multi-layer stack) is single crystalline, in some embodiments. In certain embodiments, the piezoelectric layer has fewer than 10⁹ defects/cm² (or, in some embodiments, fewer than 10⁸ defects/cm², fewer than 10⁷ defects/cm², fewer than 10⁶ defects/cm², fewer than 10⁵ defects/cm², fewer than 10⁴ defects/cm², fewer than 1000 defects/cm², fewer than 100 defects/cm², or fewer than 10 defects/cm²).

The piezoelectric layer (whether freestanding or part of the multi-layer stack) can be made from any of a variety of materials. In some embodiments, the piezoelectric layer comprises a metal oxide. In certain embodiments, the piezoelectric layer comprises a metal oxide having a perovskite, spinel, and/or garnet crystal structure. Examples of materials that can be used to form the piezoelectric layer include, but are not limited to, lead magnesium niobite-lead titanate (PMN-PT), lead zirconate titanate (PZT), zinc oxide (ZnO), barium titanate (BaTiO₃), gallium nitride (GaN), and aluminum nitride (AlN). Other piezoelectric materials are also possible.

The magnetostrictive layer (whether freestanding or part of the multi-layer stack) generally mechanically deforms (e.g., expands, contracts) in response to an applied magnetic field. In some embodiments, the magnetostrictive layer has a saturation magnetostriction coefficient (λ) of greater than or equal to 30 ppm, greater than or equal to 100 ppm, greater than or equal to 1000 ppm, greater than or equal to 2000 ppm, or greater. In some embodiments, the magnetostrictive layer has a saturation magnetostriction coefficient (λ) of greater than or equal to 30 ppm and less than or equal to 3000 ppm.

The magnetostrictive layer (whether freestanding or part of the multi-layer stack) can have a relatively small thickness, in certain embodiments. For example, referring to FIG. 2, freestanding magnetostrictive layer 200 can have a relatively small thickness 202, in some embodiments. Similarly, referring to FIGS. 4A-4B, magnetostrictive layer 404 can have a relatively small thickness, in some embodiments. In certain embodiments, the magnetostrictive layer (whether freestanding or part of the multi-layer stack) has a thickness of less than 100 micrometers, less than 10 micrometers, less than 1 micrometer, or less.

In some embodiments, the magnetostrictive layer (whether freestanding or part of the multi-layer stack) has a thickness as well as two orthogonal lateral dimensions that are orthogonal to each other as well as orthogonal to the thickness. For example, referring to FIG. 2, in accordance with certain embodiments, magnetostrictive layer 200 has thickness 202, lateral dimension 204, and a second lateral dimension 206 orthogonal to both thickness 202 and lateral dimension 204. In some embodiments, at least one of the lateral dimensions of the magnetostrictive layer is at least 10 times, at least 100 times, at least 1000 times, at least 10,000 times, at least 100,000 times, or at least 1 million times greater than the thickness of the magnetostrictive layer. In some embodiments, both of the lateral dimensions of the magnetostrictive layer are at least 10 times, at least 100 times, at least 1000 times, at least 10,000 times, at least 100,000 times, or at least 1 million times greater than the thickness of the magnetostrictive layer.

In some embodiments, the magnetostrictive layer (whether freestanding or part of the multi-layer stack) has at least one lateral dimension of at least 1 micrometer, at least 10 micrometers, at least 100 micrometers, at least 1 millimeter, or at least 10 millimeters. In some embodiments, the magnetostrictive layer (whether freestanding or part of the multi-layer stack) has a minimum lateral dimension of at least 1 micrometer, at least 10 micrometers, at least 100 micrometers, at least 1 millimeter, or at least 10 millimeters. In some embodiments, the magnetostrictive layer (whether freestanding or part of the multi-layer stack) has two lateral dimensions, each orthogonal to each other, of at least 1 micrometer, at least 10 micrometers, at least 100 micrometers, at least 1 millimeter, or at least 10 millimeters.

The magnetostrictive layer (whether freestanding or part of the multi-layer stack) is single crystalline, in some embodiments. In certain embodiments, the magnetostrictive layer has fewer than 10⁹ defects/cm² (or, in some embodiments, fewer than 10⁸ defects/cm², fewer than 10⁷ defects/cm², fewer than 10⁶ defects/cm², fewer than 10⁵ defects/cm², fewer than 10⁴ defects/cm², fewer than 1000 defects/cm², fewer than 100 defects/cm², or fewer than 10 defects/cm²).

The magnetostrictive layer (whether freestanding or part of the multi-layer stack) can be made from any of a variety of materials. In some embodiments, the magnetostrictive layer comprises a metal oxide. In certain embodiments, the magnetostrictive layer comprises a metal oxide having a perovskite, spinel, and/or garnet crystal structure. Examples of materials that can be used to form the magnetostrictive layer include, but are not limited to, cobalt ferrite (CoFe₂O₄ or CFO), nickel (Ni), nickel ferrite (NiFe₂O₄ or NFO), Terfenol-D (Tb_{0.3}Dy_{0.7}Fe_{1.93}), samarium iron alloy (SmFe₂), and terbium iron alloy (TbFe₂). Other magnetostrictive materials are also possible.

In accordance with certain embodiments, the ability to manipulate freestanding piezoelectric layers and freestanding magnetostrictive layers can allow one to incorporate a variety of types of substrates in the multi-layer stack. In some embodiments, for example, the stack substrate can be made of a polymer, a metal, a ceramic, or combinations of these or other materials. In some embodiments, the stack substrate is relatively thin (e.g., having a thickness of less than 1 millimeter, less than 500 micrometers, less than 100 micrometers, less than 10 micrometers, or less). In some embodiments, the stack substrate is in the form of a layer. In certain embodiments, the stack substrate has a thickness as well as two orthogonal lateral dimensions that are orthogonal to each other as well as orthogonal to the thickness. In some embodiments, at least one of the lateral dimensions of the stack substrate is at least 10 times, at least 100 times, at least 1000 times, at least 10,000 times, at least 100,000 times, or at least 1 million times greater than the thickness of the stack substrate. In some embodiments, both of the lateral dimensions of the stack substrate are at least 10 times, at least 100 times, at least 1000 times, at least 10,000 times, at least 100,000 times, or at least 1 million times greater than the thickness of the stack substrate.

In certain embodiments, the stack substrate is flexible. In some embodiments, the stack substrate has a Young's modulus, as measured by ASTM test E111, of less than 100 MPa, less than 75 MPa, less than 50 MPa, or less.

It should be understood that when a structure is referred to as being “on”, “over”, “under”, “on top of”, or “underneath”, another structure, these terms are used to indicate relative positioning of the structures, and that the terms are meant to be used in such a way that the relative positioning of the structures is independent of the orientation of the combined structures or the vantage point of an observer. Additionally, it should also be understood that when a structure is referred to as being “on” or “over” another structure, it may cover the entire structure, or a portion of the structure. Similarly, it should be understood that when a structure is referred to as being “under” another structure, it may be covered by the entire structure, or a portion of the structure.

In addition, when a first structure is referred to as being “on,” “over,” or “on top of” a second structure, the first structure can be directly on the second structure, or an intervening structure (e.g., a layer, a gap) also may be present between the first structure and the second structure. Similarly, when a first structure is “under” or “underneath” a second structure, the first structure can be directly under the second structure, or an intervening structure (e.g., a layer, a gap) also may be present between the first structure and the second structure. A first structure that is “directly on,” “directly under,” or “in direct contact with” a second structure means that no intervening structure is present between the first structure and the second structure.

The following example is intended to illustrate certain embodiments of the present invention, but does not exemplify the full scope of the invention.

### EXAMPLE

This example describes the fabrication and testing of an exemplary multi-layer stack, in accordance with certain embodiments. The multi-layer stack can be used, for example, as an electrical switch.

Complex-oxide materials exhibit a vast range of functional properties desirable for next-generation electronic, spintronic, magnetoelectric (ME), neuromorphic, and energy conversion storage devices. Their physical functionalities can be well coupled by joining them to create heterostructures and further boosted by applying strain. The predominant method for heterogeneous integration and application of strain has been through heteroepitaxy, which unfortunately drastically limits the breadth of possible material combinations and integrability of complex oxides with, for example, mature semiconductor technologies. Moreover, key physical properties of complex-oxide thin films, such as piezoelectricity and magnetostriction, are generally severely reduced by the substrate clamping effect. Demonstrated here is a universal mechanical exfoliation method to produce freestanding single-crystalline membranes from a wide range of complex-oxide materials including perovskite, spinel, and garnet crystal structures with varying crystallographic orientations. Also, artificial heterostructures were created and their physical properties were hybridized by directly stacking freestanding membranes with different crystal structures and orientations, not possible by conventional methods. The results establish a platform for stacking and coupling 3D structures, akin to 2D material-based heterostructures, for enhancing device functionalities.

Traditionally, heterogeneous coupling and control of strain for crystalline films are carried out through heteroepitaxy on lattice-mismatched substrates. Epitaxial methods, however, generally have fundamental limitations which prevent unrestricted manipulation, integration, and utilization of these materials. First, heteroepitaxy generally occurs only for different materials whose lattice constant or crystal structures are within a certain threshold. Thus, heterostructuring via epitaxy is allowed for relatively limited material systems. Moreover, the degree of strain that can be applied to an epitaxial layer is generally fixed by pseudomorphic epitaxial conditions. Second, the epitaxial film is generally clamped by the substrate, constraining several important properties. For example, piezoelectric and magnetostrictive responses are dampened by approximately an order of magnitude due to the substrate clamping effect, reducing their sensitivity and maximum response. Third, epitaxial growth typically requires elevated temperatures often preventing the epitaxial integration of materials that are stable in much different environments or are thermodynamically unstable in contact with each other; such instability typically precludes the epitaxial integration of complex oxides with mainstream semiconductor materials. Thus, it has been extremely challenging to form heterostructures between materials with large lattice mismatch or between material integration choices based solely on the desired properties they would bring to an artificial heterostructure, and even more challenging to unclamp epitaxial films from the substrate. Freestanding heterostructures without any limitations in crystal structures are often demonstrated in 2D material systems by stacking ultrathin layers (a few atoms thick) of 2D materials, and the concept of layer transfer of single materials or various individual devices composed of nanomaterials onto foreign substrates have been demonstrated in the past. However, artificial heterostructuring of multiple single-crystalline membranes and robust physical coupling, experimentally demonstrated here, have been elusive to date. While chemical lift-off of oxide materials has been reported, this method is only applicable to a limited range of material systems due to the lattice mismatch and etch selectivity constraints between the epitaxial layer, sacrificial layer, and the substrate. Additionally, slow release rate is generally a well-known shortcoming of chemical lift-off for larger substrates.

Demonstrated here were artificial complex-oxide heterostructure stacks by utilizing mechanical lift-off techniques, where the epitaxial oxide films were essentially instantly separated from weakened epitaxial interfaces to form freestanding single-crystalline membranes. These techniques can, in theory, be universally applied to prepare freestanding membranes across a broad range of crystal structures (e.g. perovskite, spinel, and garnet) with the potential capability of reusing the host oxide substrate. Unprecedentedly, freestanding membranes were demonstrated from several important oxide structures including archetypal perovskite SrTiO₃ (STO), perovskite BaTiO₃ (BTO), spinel CoFe₂O₄ (CFO), garnet Y₃Fe₅O₁₂ (YIG), and a perovskite of complex composition Pb(Mg_{1/3}Nb_{2/3})O₃—PbTiO₃ (PMN-PT). Single-crystalline STO, BTO, CFO, and YIG were remote-epitaxially (i.e. epitaxial growth of thin films seeded by the underlying substrate through a few continuous layers of graphene) grown on graphene-coated STO, MgAl₂O₄ (MAO), and Gd₃Ga₅O₁₂ (GGG) substrates, respectively followed by mechanical exfoliation. Also demonstrated were single-crystalline freestanding membranes of PMN-PT that were grown via sputtering which damages graphene. This was achieved by discovering that SrRuO₃ (SRO) can provide a weak interface for PMN-PT, allowing PMN-PT films to be mechanically released precisely at the PMN-PT/SRO interface without graphene. From these freestanding membranes, various heterostructures were fabricated to couple their unique properties by directly stacking them. Enhanced magnetoelectric (ME) coupling was observed by stacking magnetostrictive CFO and piezoelectric PMN-PT, as their physical properties can be greatly enhanced in freestanding form by being declamped from the substrate. Also demonstrated was magnetostatic and magnetoelastic coupling in a CFO/YIG membrane heterostructure. Electrical coupling of graphene sandwiched between freestanding CFO and YIG membranes was verified by tracing the Fermi level shift with respect to the Dirac point of graphene. These findings advanced oxide research by allowing unrestricted integration of single-crystalline dissimilar complex-oxide membranes into elaborate heterostructures unattainable by epitaxy and chemical lift-off methods, which creates opportunities to produce unprecedented 3D heterostructures not yet demonstrated from various freestanding 2D or 3D membranes.

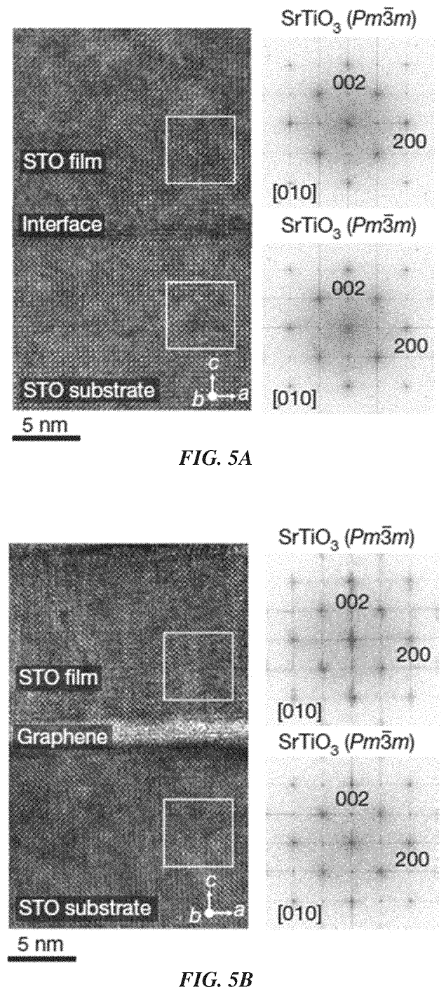

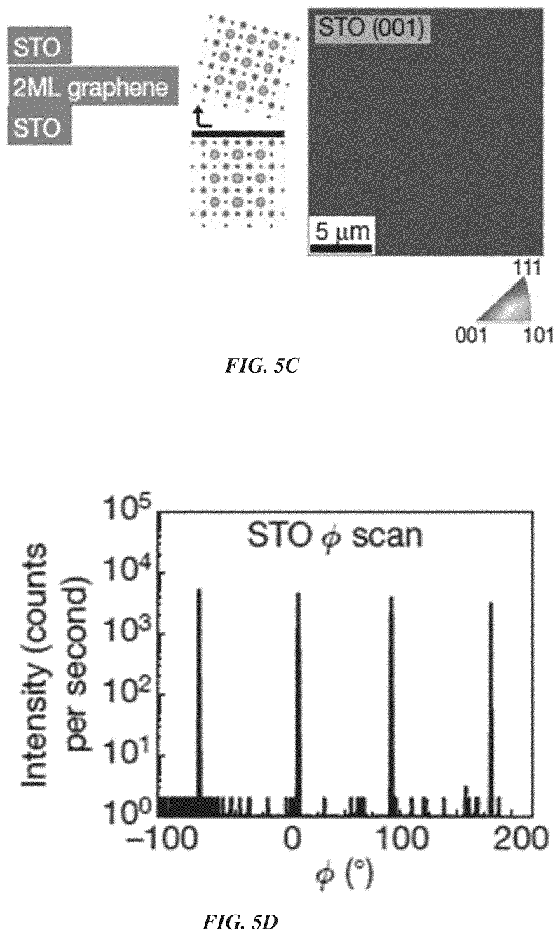

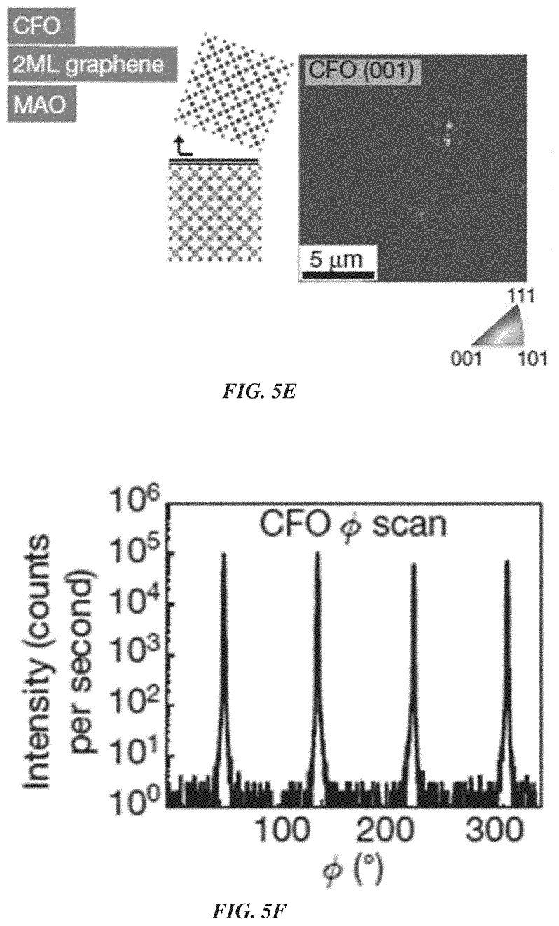

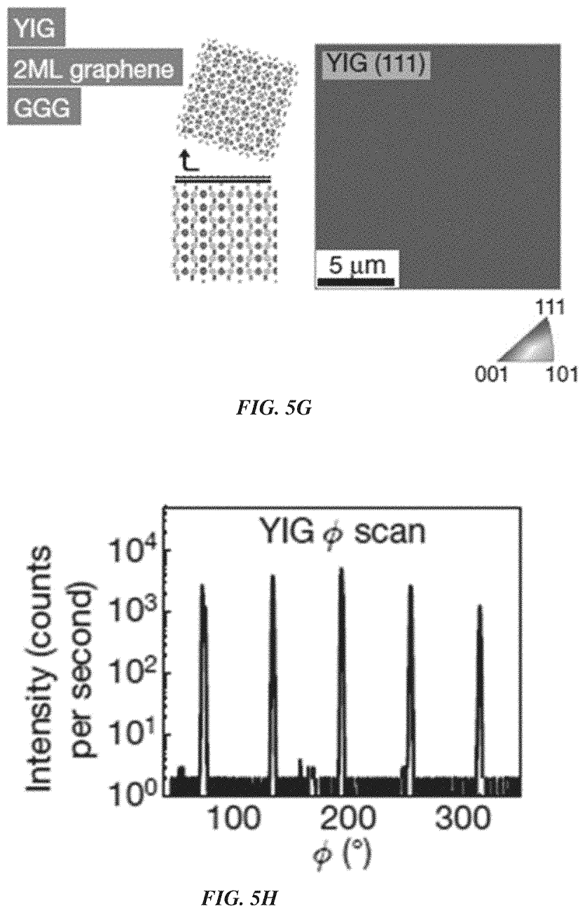

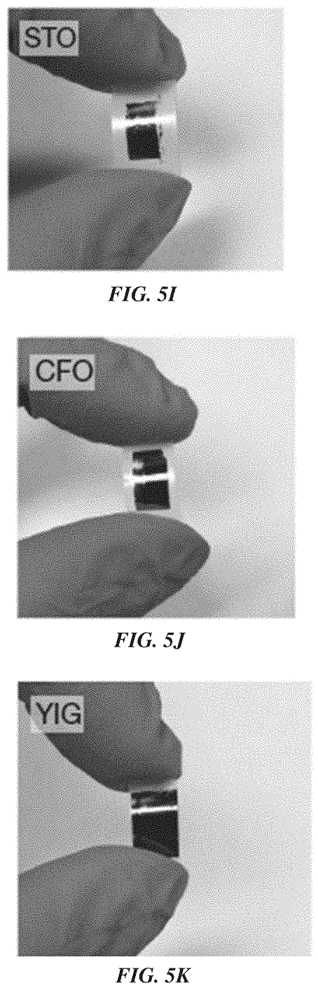

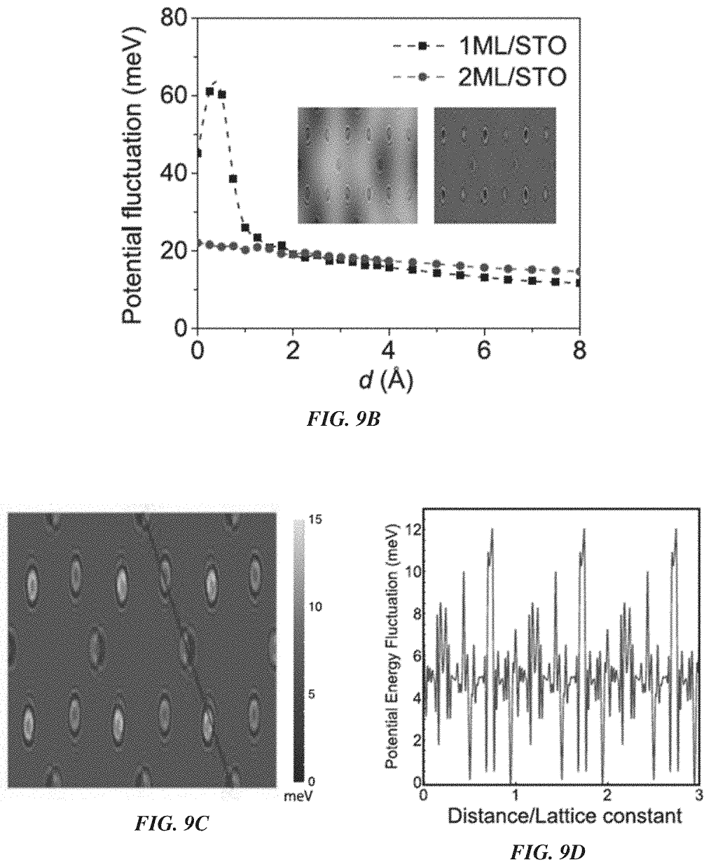

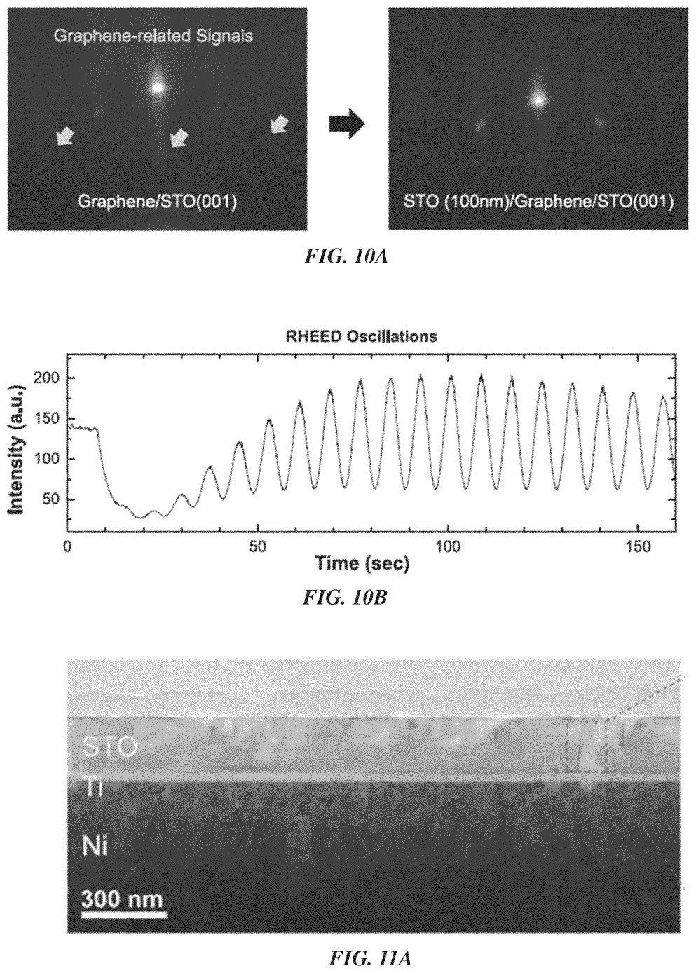

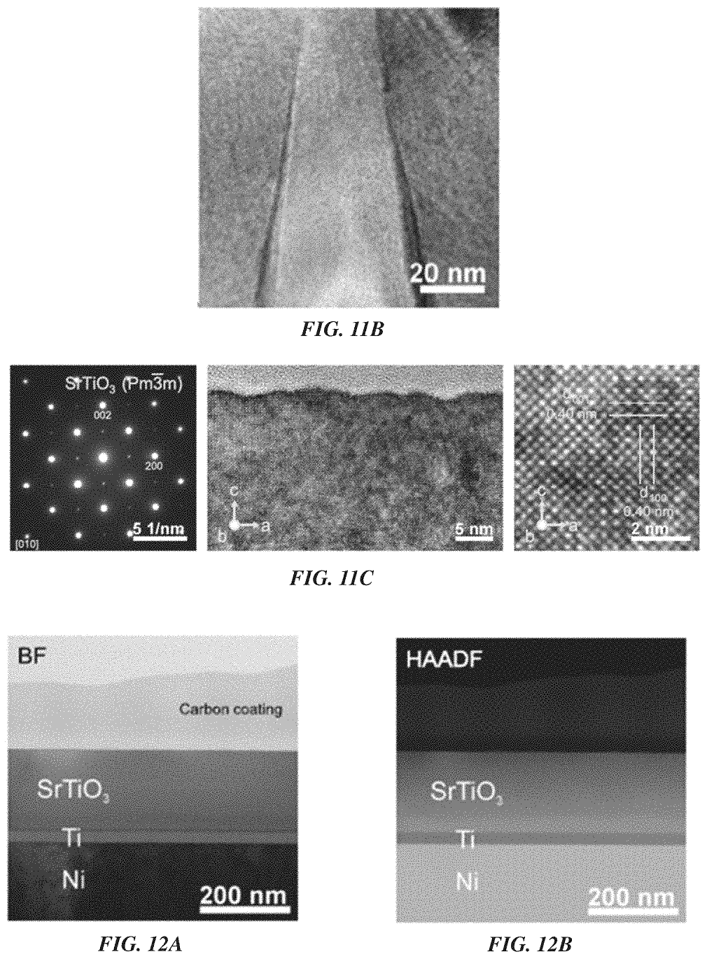

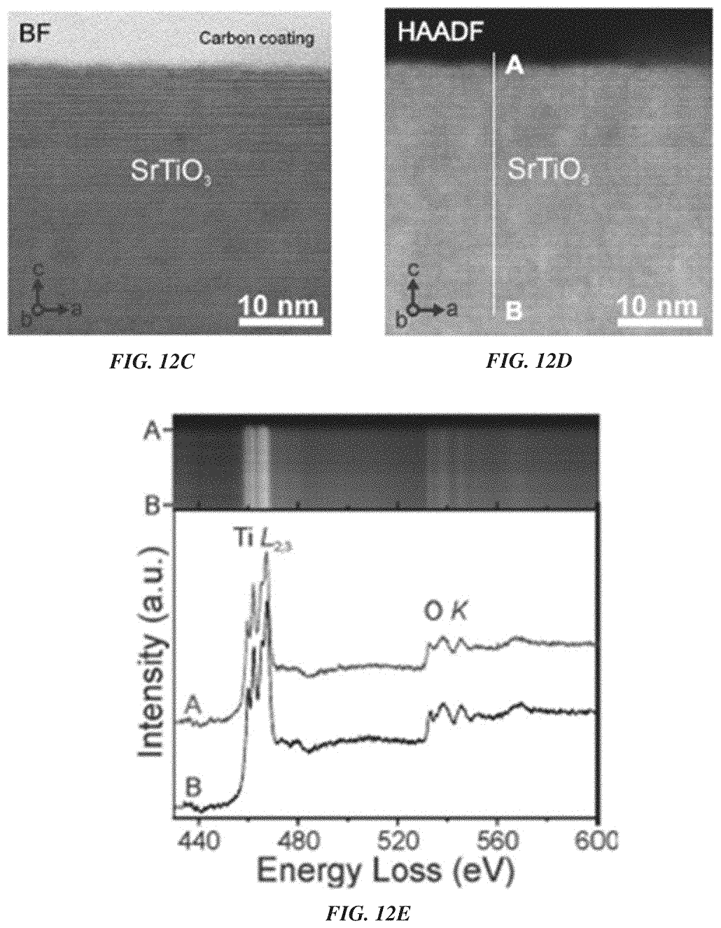

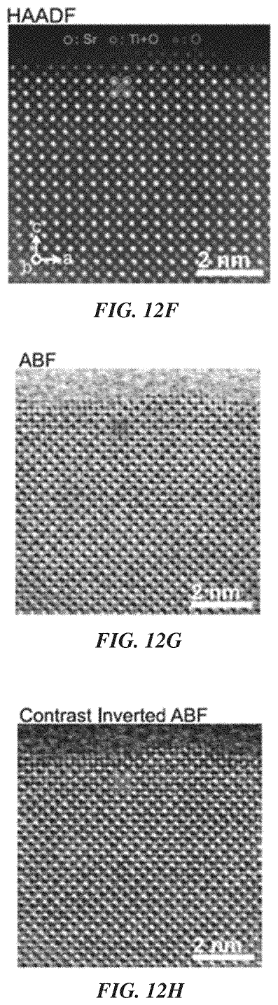

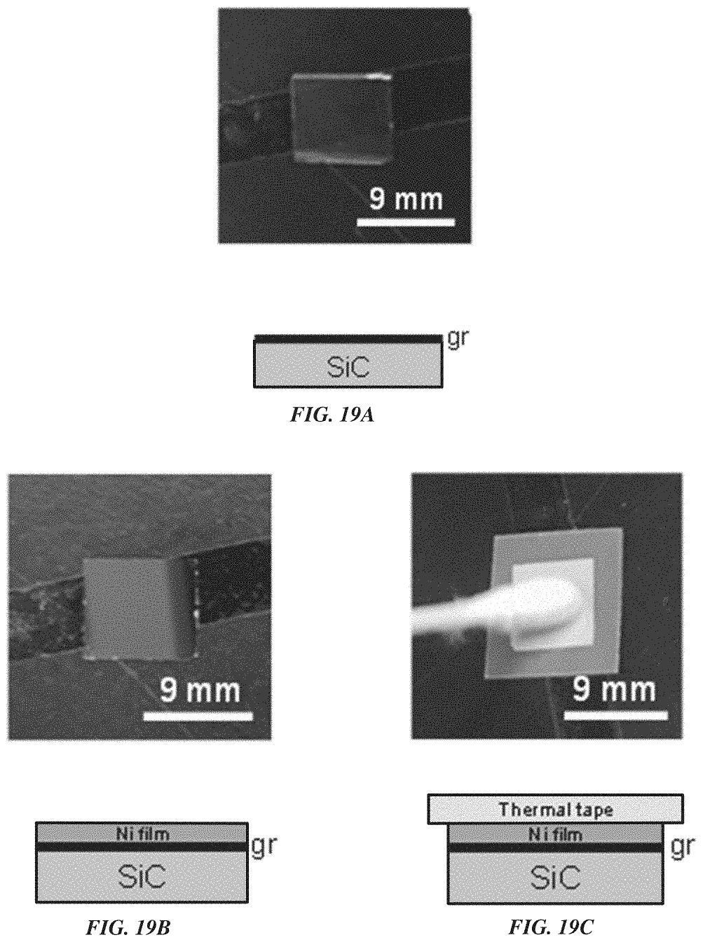

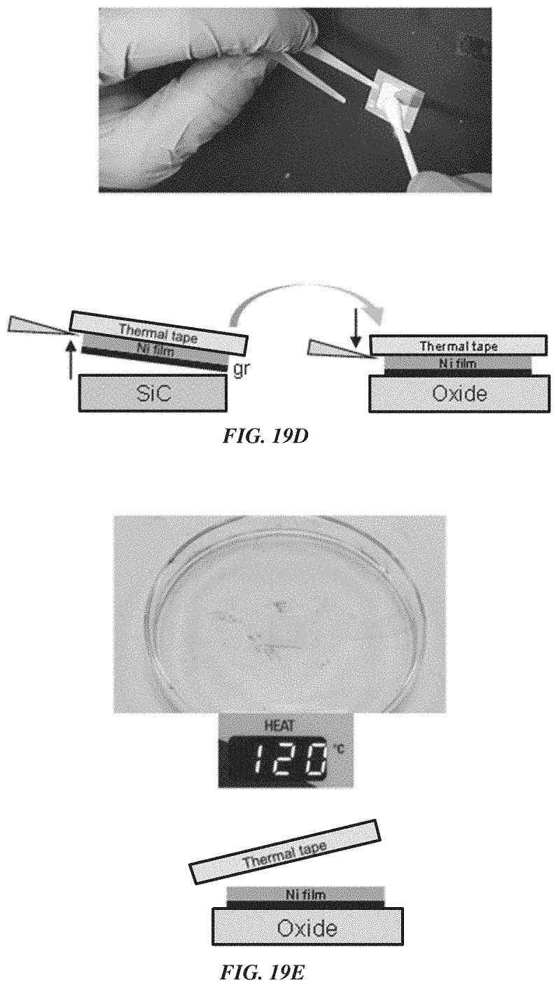

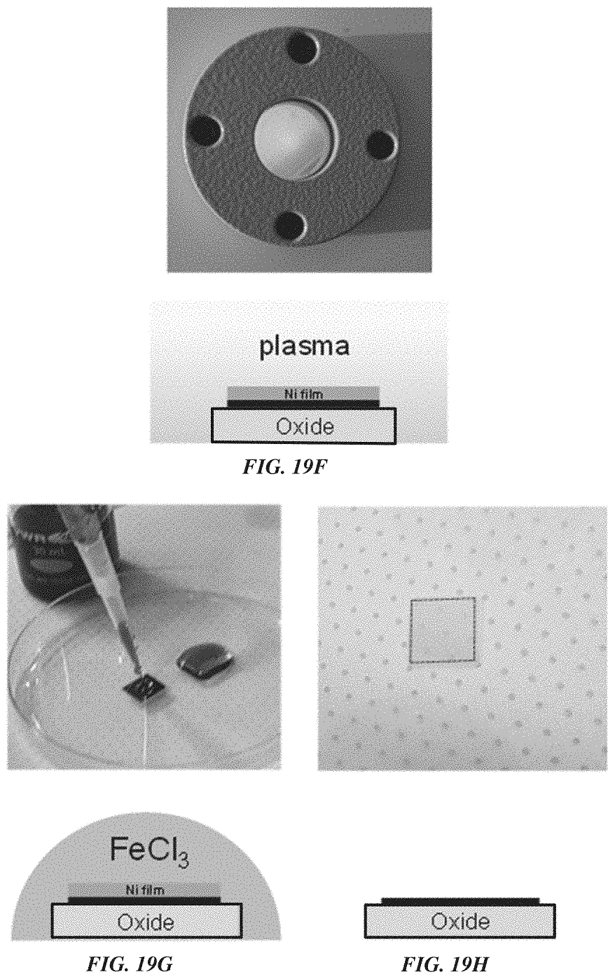

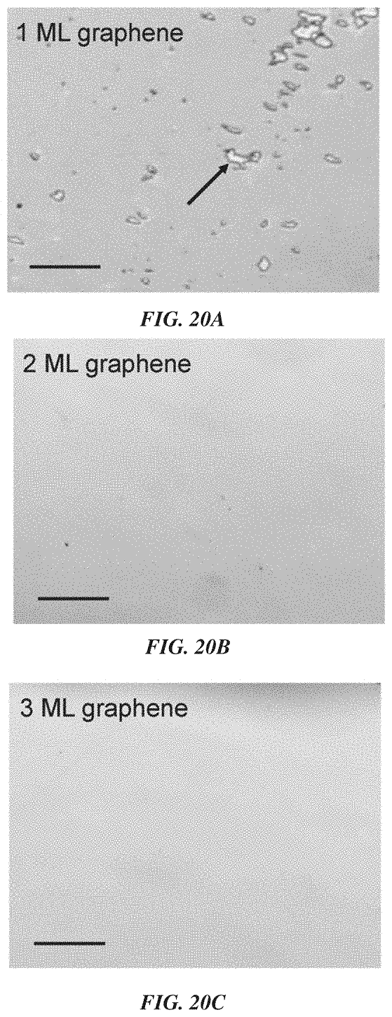

The growth dynamics of STO films on graphene-coated STO (001) substrates was studied first (FIGS. 19A-19H). DFT calculation suggested that atomic potential fields can penetrate completely through bilayer graphene and partially through trilayer graphene (FIGS. 9A-9D), thus allowing successful remote epitaxy up to two monolayers of graphene interlayers. Pulsed-laser deposition (PLD) experimental results precisely followed the prediction as single-crystalline STO films were successfully grown through bilayer graphene interlayers proving successful seeding from the STO substrates through graphene. In-situ high-pressure reflection high-energy electron diffraction (RHEED) during growth also showed clear intensity oscillations and crystallinity of the film during growth (FIGS. 10A-10B). In contrast to epitaxy of semiconductors such as III-V and III-Nitrides on graphene where the adatoms or substrate do not react with graphene, it was generally important to avoid oxidation of graphene for epitaxy of oxides to ensure the release of remote epitaxial STO. Initially, the STO films grown in a conventional oxygen ambient were unable to be exfoliated due to the graphene being etched during the nucleation stage from the substrate as evidenced by the absence of graphene in XTEM (FIG. 5A). In order to protect the graphene, an ultrathin STO buffer (˜5−10 nm), which is not grown in a conventional oxygen ambient, but in vacuum (<5×10−6 Torr), was deposited. By applying this buffer, the graphene was preserved (FIG. 5B), resulting in successful production of freestanding STO membranes (FIG. 11A-11C). Electron backscatter diffraction (EBSD) map of the STO film (FIG. 5C) showed (001) cubic orientation over a large area. Additionally, azimuthal x-ray diffraction (XRD) ϕ scan confirmed in-plane single-crystallinity without any rotated domains (FIG. 5D). Electron energy loss spectroscopy (EELS) verified that further growth of STO in an oxygen ambient effectively corrected the oxygen stoichiometry of the entire STO film, even the region grown in vacuum (FIGS. 12A-12H). Because the STO substrate was also a source of oxygen, the exfoliation area yield of the sample with one monolayer graphene was low compared to the exfoliation area yield of samples with two or more graphene layers (FIGS. 20A-20C). Through these findings, two graphene layers were determined to achieve the highest ratio of crystal quality to exfoliation yield.

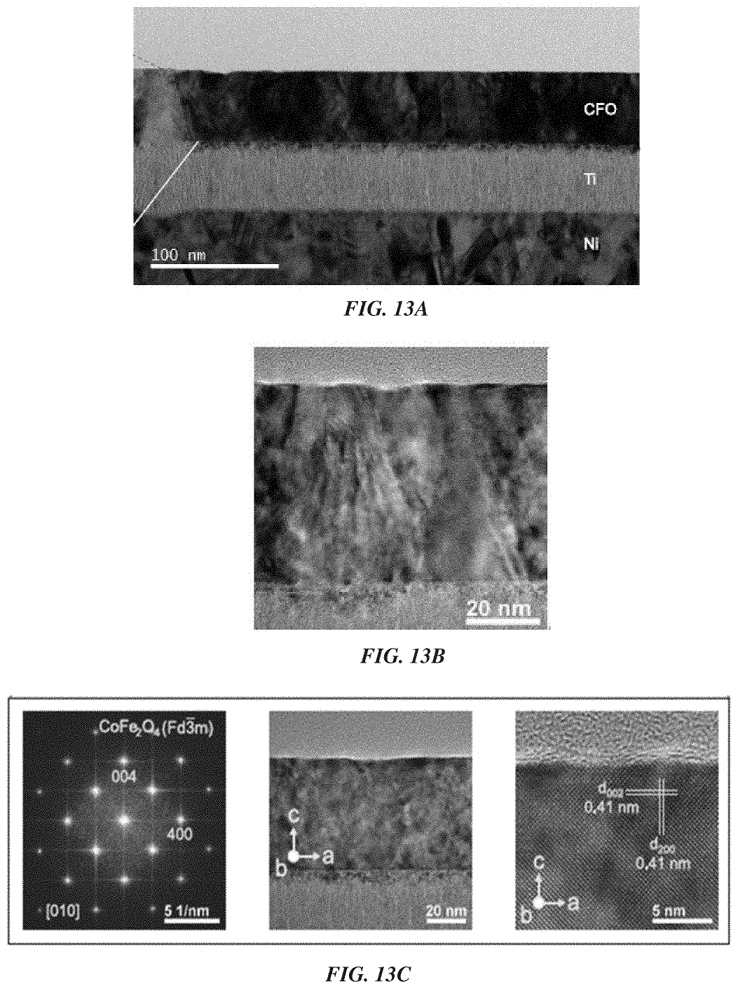

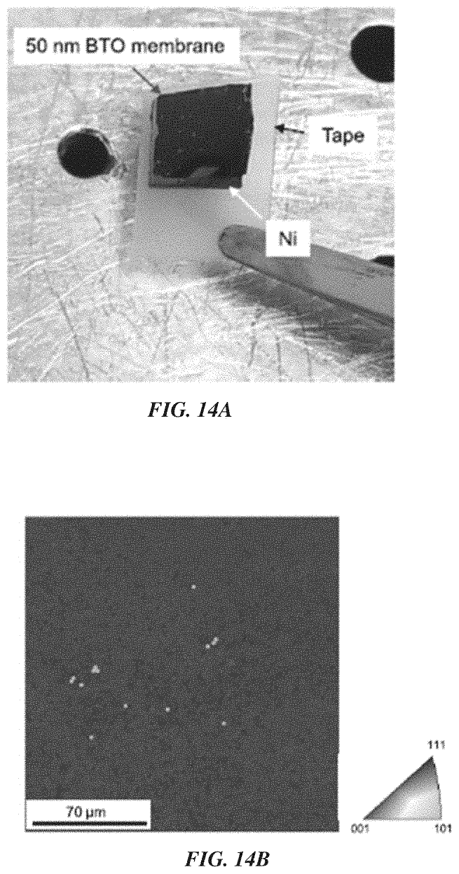

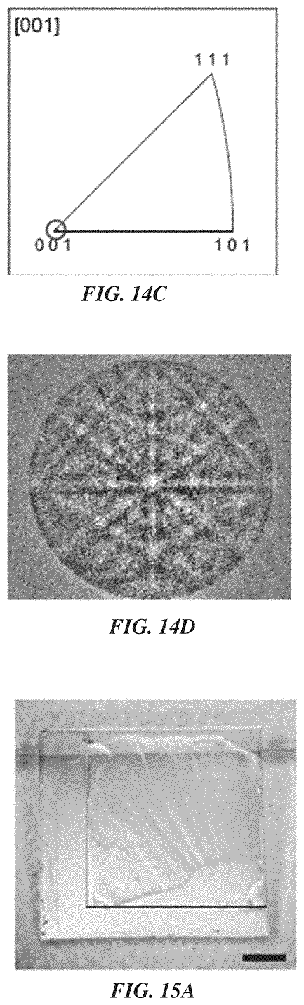

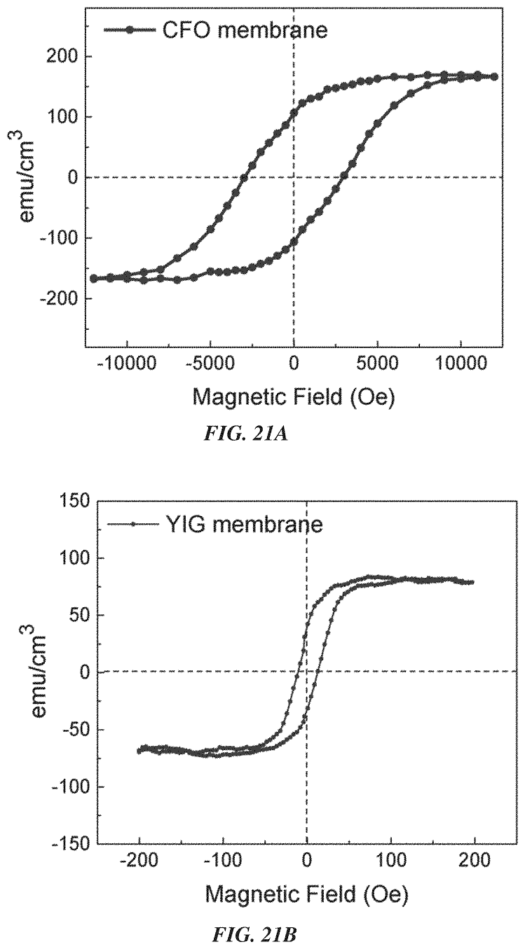

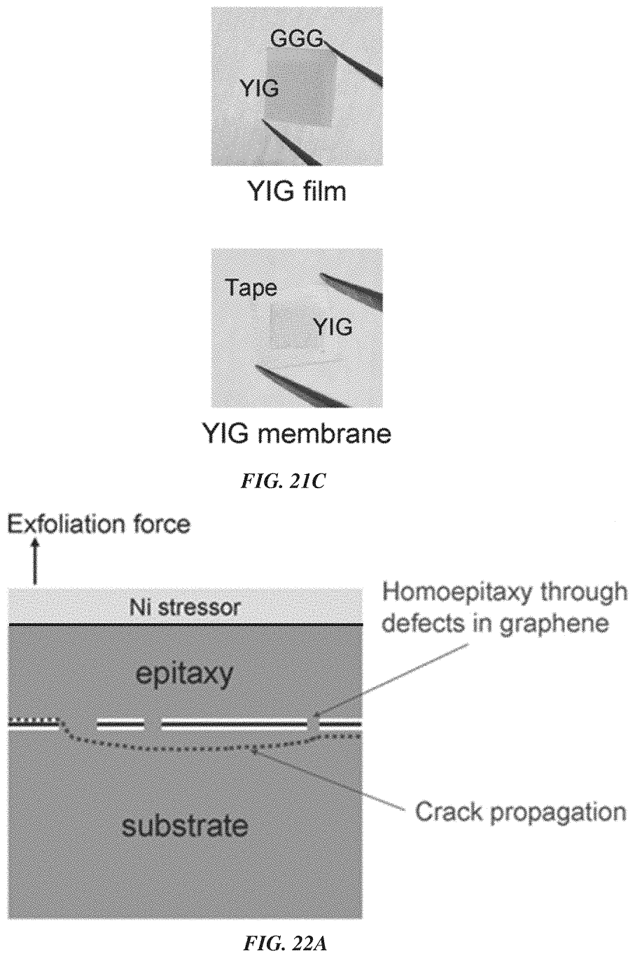

As representative cases for spinel and garnet oxides, spinel CFO and garnet YIG were grown on graphene-coated MAO (001) and GGG (111) substrates, respectively. Single crystallinity of the grown film was again verified by EBSD and HRXRD (FIGS. 5E-5H). Magnetization values of freestanding CFO and YIG were within reasonable range from bulk values, proving good quality of freestanding single-crystalline membranes (FIGS. 21A-21C). Cross-sectional TEM measurements were performed on the exfoliated CFO membrane to confirm the crystallinity at an atomic scale. Amid the single crystalline matrix, localized polycrystalline domains were observed (FIGS. 13A-13C). The case was similar for other remote epitaxial membranes as well (FIGS. 11A-11C). These polycrystalline domains were likely caused by regions of non-uniform graphene thickness or organic/metal residues left from graphene transfer and due to the high sticking coefficient of oxide adatoms. Thus, the quality of the transferred graphene on the substrate determined the exfoliation area and crystallinity of the epitaxial film. Regardless, applying a thin protection layer before growing under an oxygen environment was effective for all materials explored here as all epitaxial films were successfully released from the substrate. The resulting flexible STO, CFO, and YIG membranes with a thickness of 100 nm are shown in FIGS. 5I-5K, supported by a flexible handling tape. Moreover, the compatibility of this process was verified using molecular-beam epitaxy (MBE), another common technique to grow single-crystalline complex-oxide films, by growing BTO on graphene-coated STO substrates and exfoliating the BTO film. Single-crystalline BTO membranes were produced, similar to the results obtained by PLD (FIGS. 14A-14D).

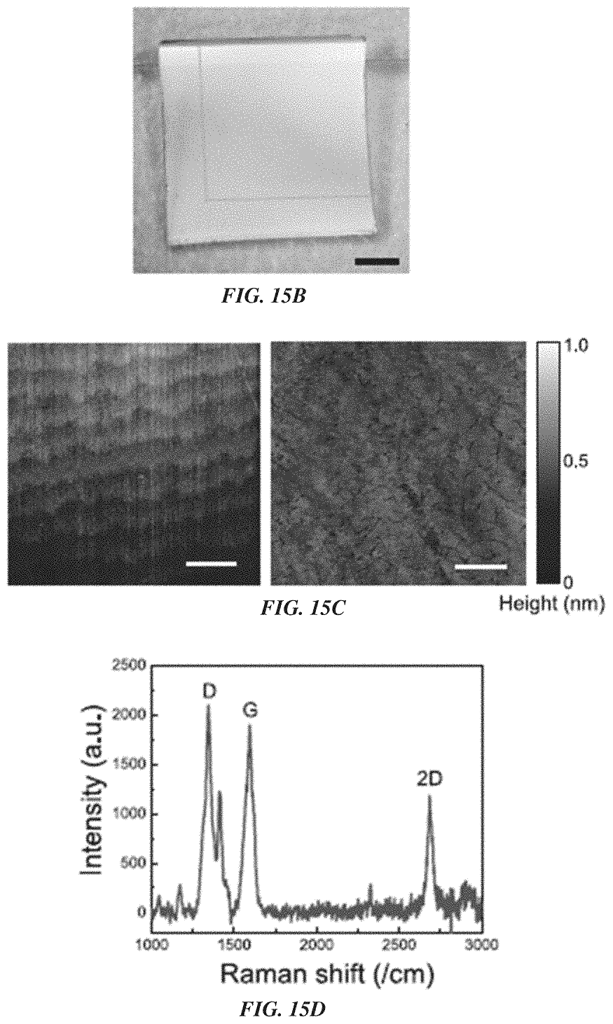

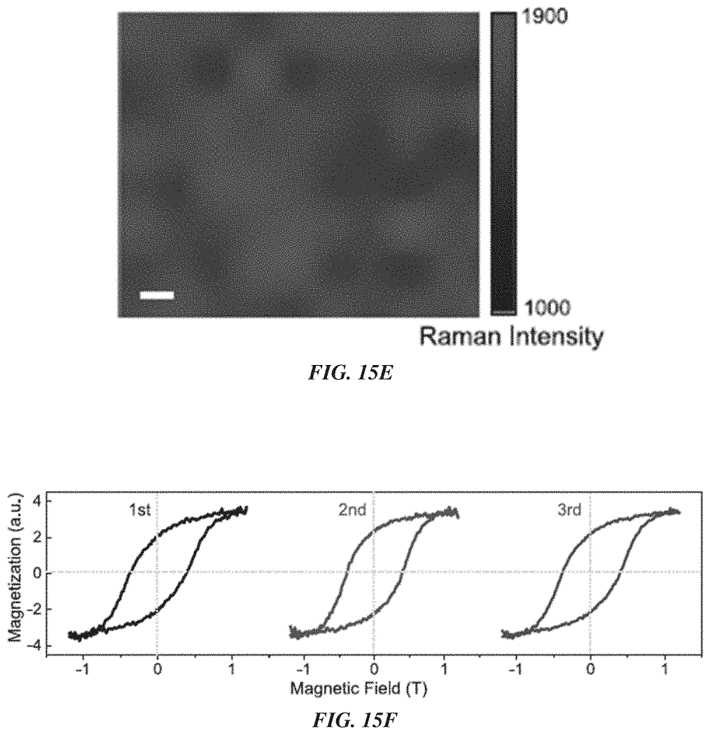

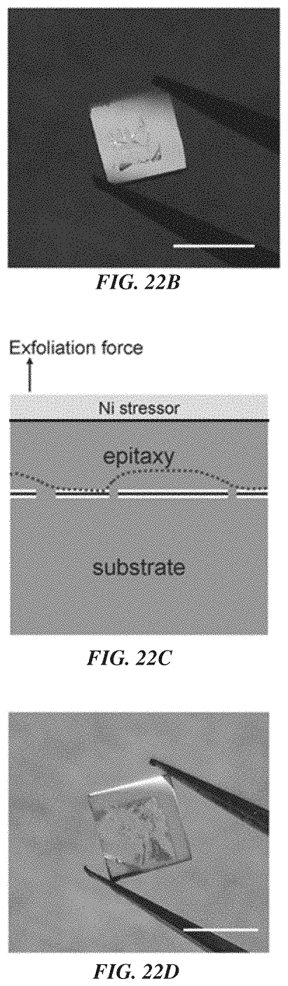

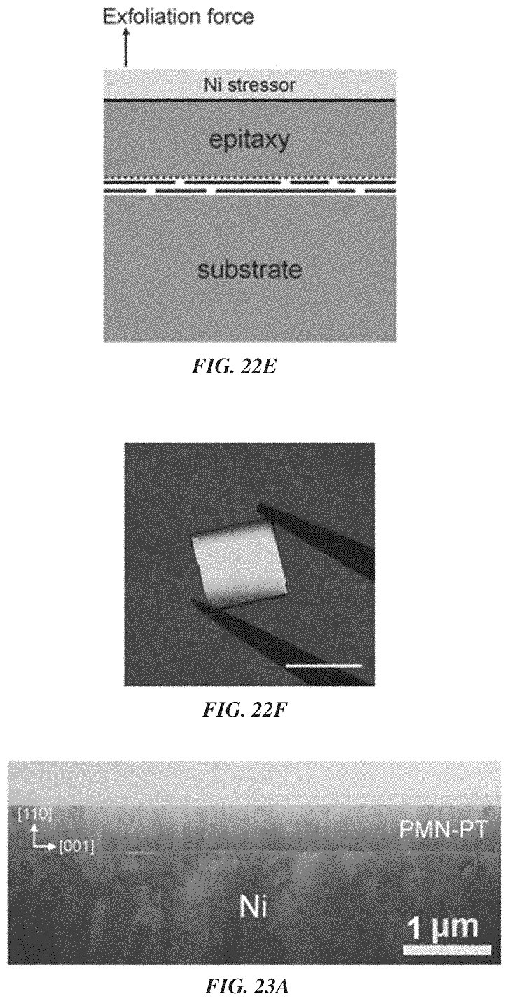

It was also discovered that the bilayer graphene interlayer not only enhanced exfoliation yield, but also reduced damage to the substrate upon peeling, thus promoting reusability of the substrates. Multiple CFO freestanding membranes were obtained by reusing a single graphene-coated MAO substrate three times. Magnetic hysteresis measured from freestanding CFO using vibrating sample magnetometry (VSM) were consistent throughout each exfoliation, confirming the reusability of the MAO substrate. It is believed that this was the first demonstration to show wafer reusability for producing freestanding complex oxides, which drastically reduced production costs for applications (FIGS. 15A-15F and FIGS. 22A-22F).

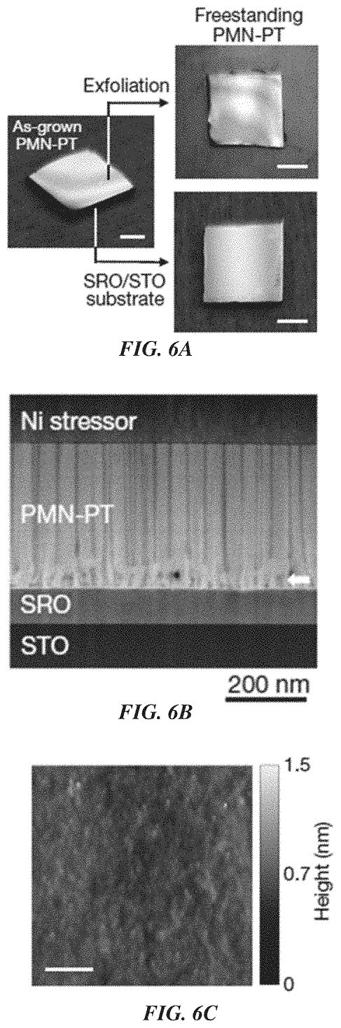

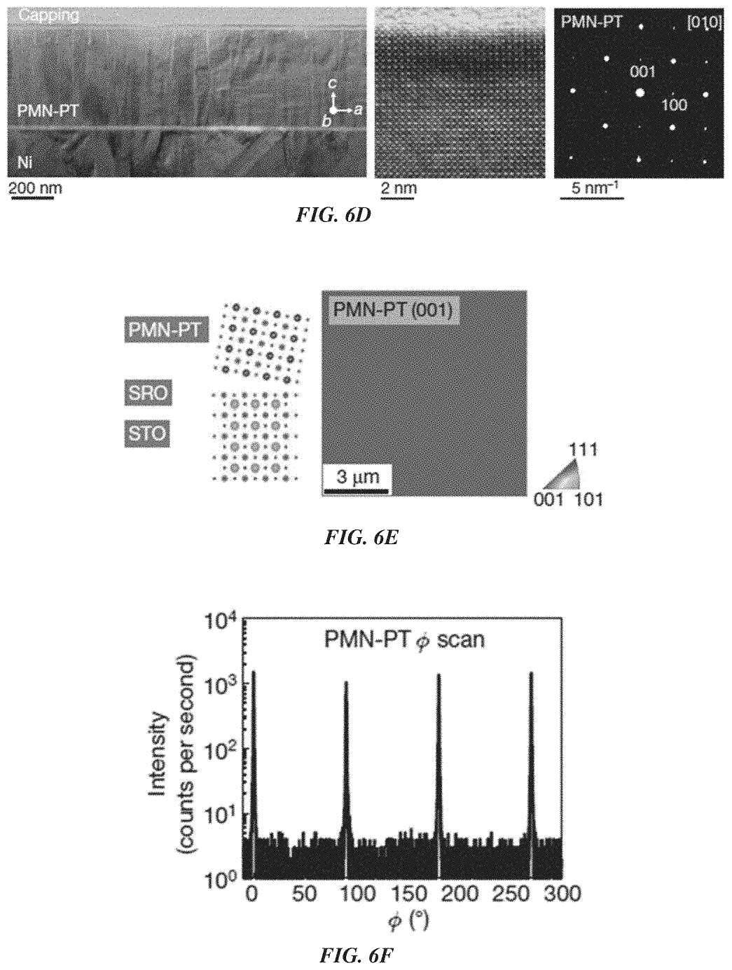

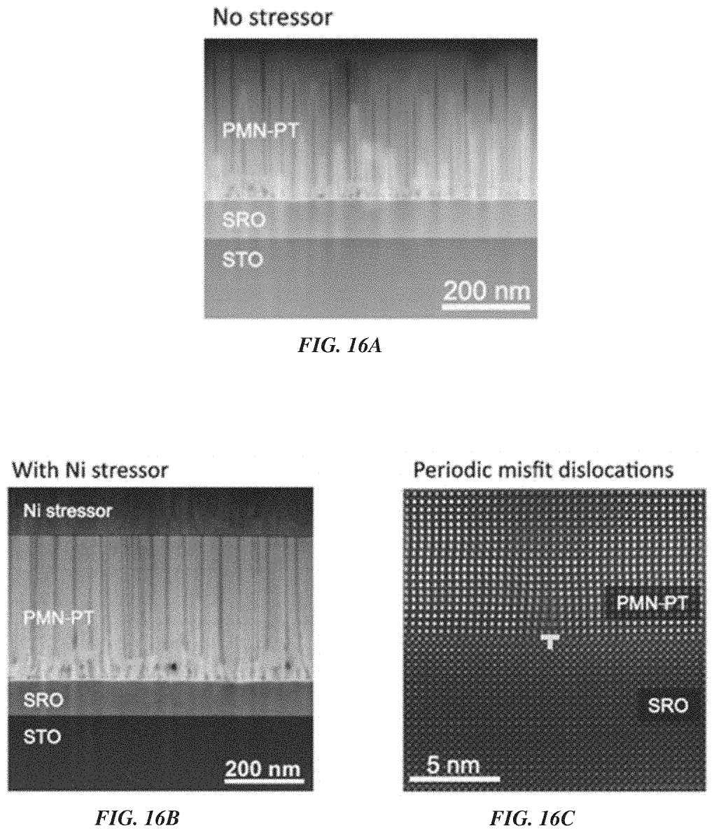

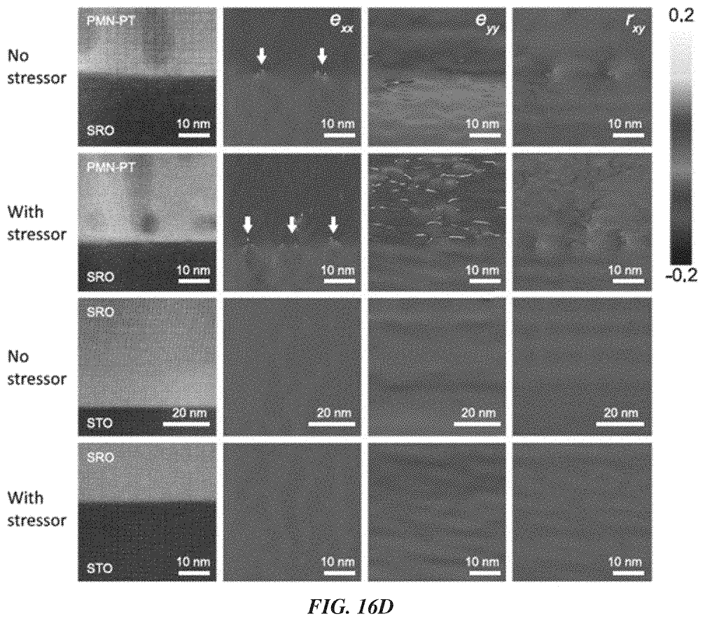

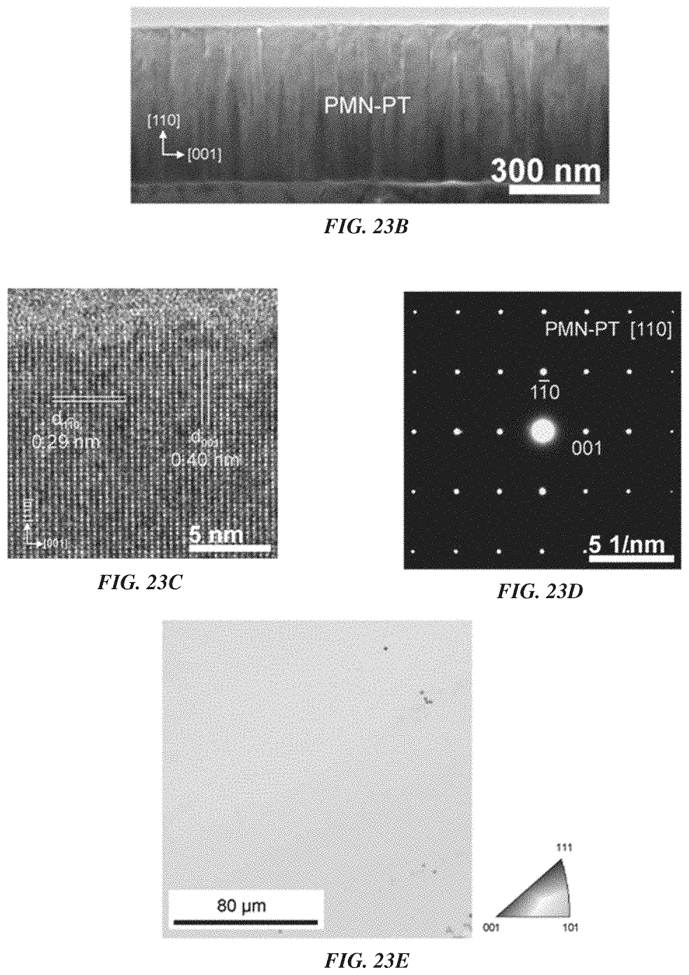

The mechanical exfoliation technique was further broadened to oxides with more complex compositions such as PMN-PT. Single-crystalline PMN-PT films were prepared previously by sputtering. Consequently, in those cases, remote epitaxy strategies could not be applied due to the harsh plasma ambient which rapidly etches graphene. It was discovered that PMN-PT was weakly bonded to SRO, allowing mechanical exfoliation of PMN-PT with near atomic precision. For this, 500 nm PMN-PT/100 nm SRO epitaxial heterostructures were grown on STO substrates by sputtering without graphene, followed by the deposition of a 3-5 micrometer Ni stressor layer with a stress of around 800 MPa. Upon mechanical exfoliation, the Ni stressor provided enough strain energy to guide the crack propagation precisely at the PMN-PT/SRO interface with minimum damage to the substrate (FIG. 6A). As shown in the HAADF-STEM image in FIG. 6B, the PMN-PT/SRO interface is severely strained while the SRO/STO interface is pristine. After depositing high stress Ni on PMN-PT, indications of an increased strain at the interface was observed. Geometric phase analysis (GPA) revealed that a closely spaced network of misfit dislocations (spaced ˜20 nm apart) applied strain at the interface while the Ni stressor provided additional stress to the PMN-PT/SRO interface (FIGS. 16A-16D). It was speculated that the resulting concentrated strain field at the PMN-PT/SRO interface provided a sufficiently weak interface to allow atomically precise crack propagation. The precise crack propagation through the PMN-PT/SRO interface was reproducibly verified by AFM on the exfoliated SRO surface, which showed an RMS roughness of ˜2 Å (FIG. 6C). Cross-sectional TEM investigation on the exfoliated PMN-PT membranes revealed high crystalline quality as well as relieved strain at the PMN-PT surface that was bonded to the SRO before exfoliation (FIG. 6D). Single-crystallinity over a large area was confirmed by EBSD mapping and azimuthal ϕ scans (FIGS. 6E-6F). In TEM, diffraction patterns taken from all imaged areas showed a single (001) orientation consistent with other characterization. This technique also worked for (110) PMN-PT films grown on SRO/STO (FIGS. 23A-23E). While details of the mechanism for the weakened interface between SRO and PMN-PT still remain to be verified, this finding further broadened complex oxide material systems that can be produced as freestanding membranes and provided opportunities to develop a graphene-free layer release process by further exploring interface strain engineering.

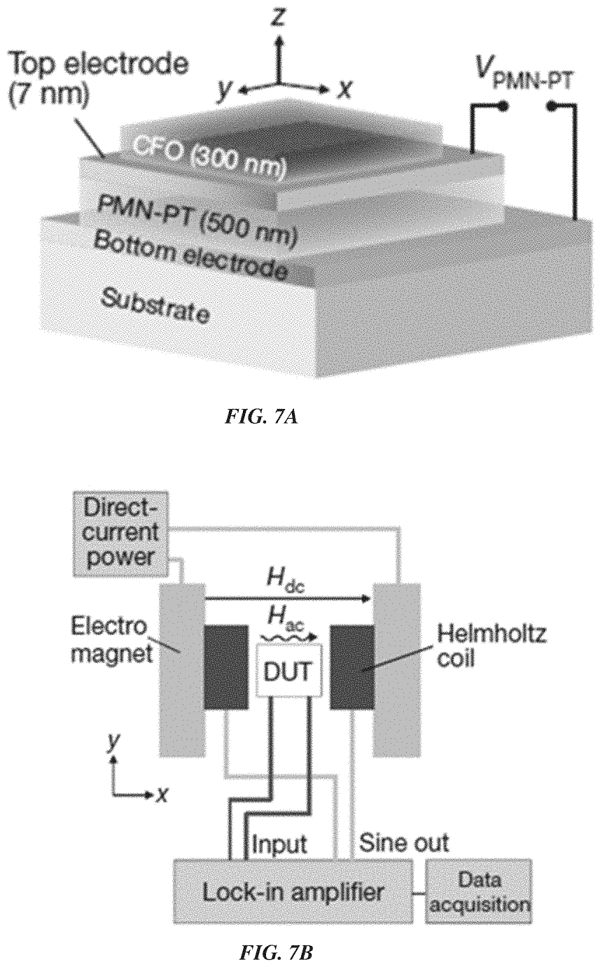

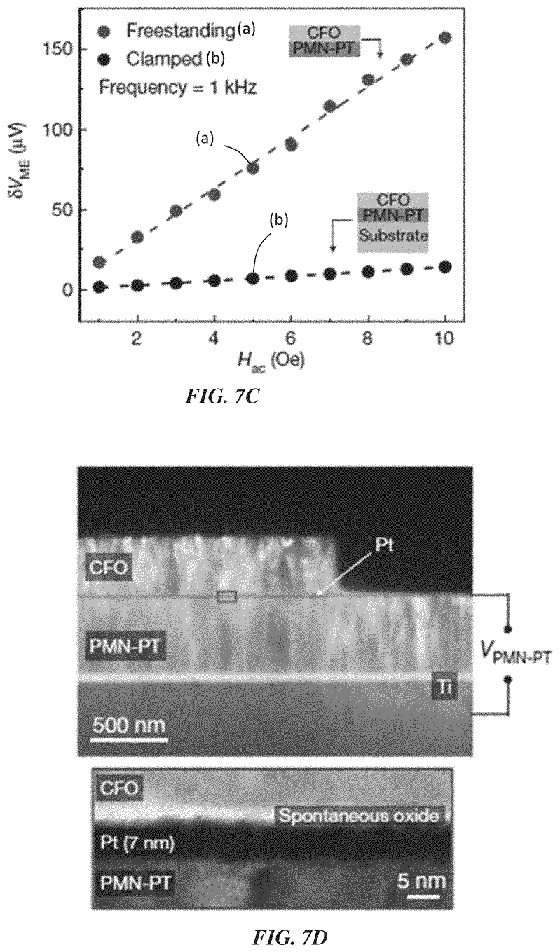

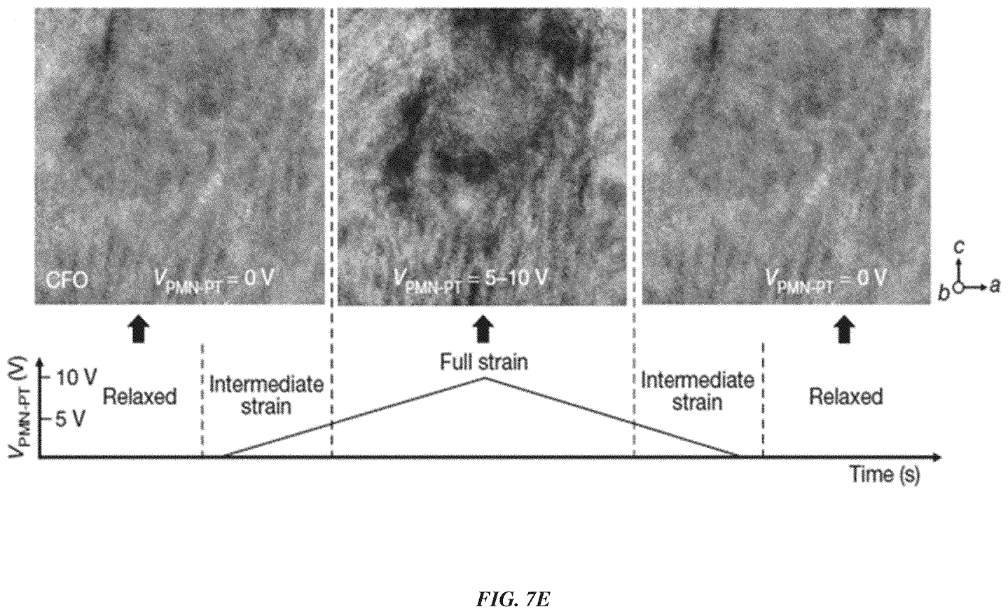

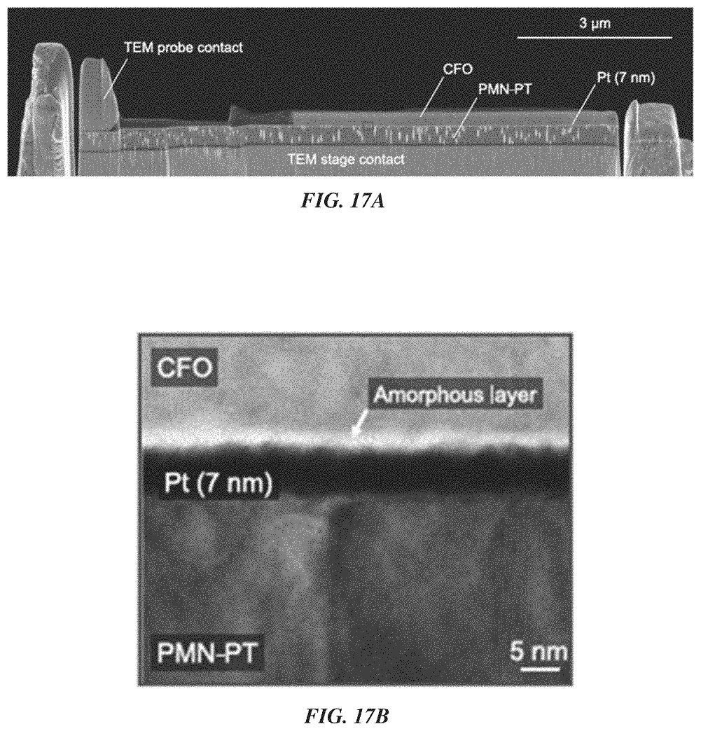

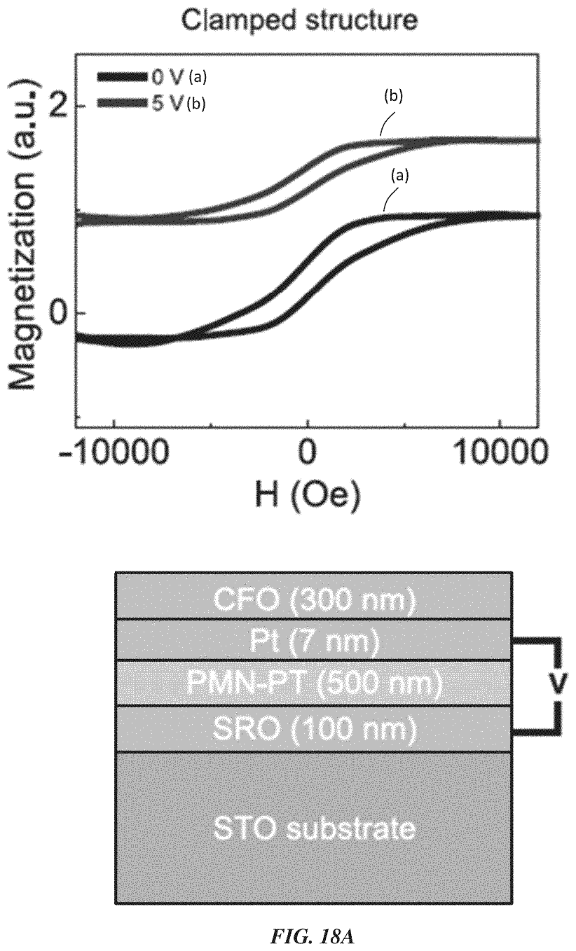

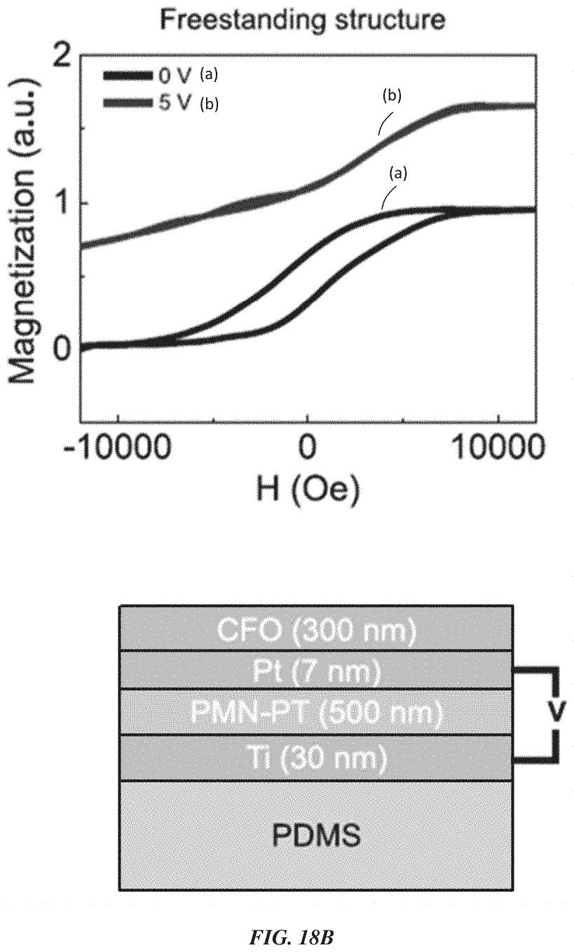

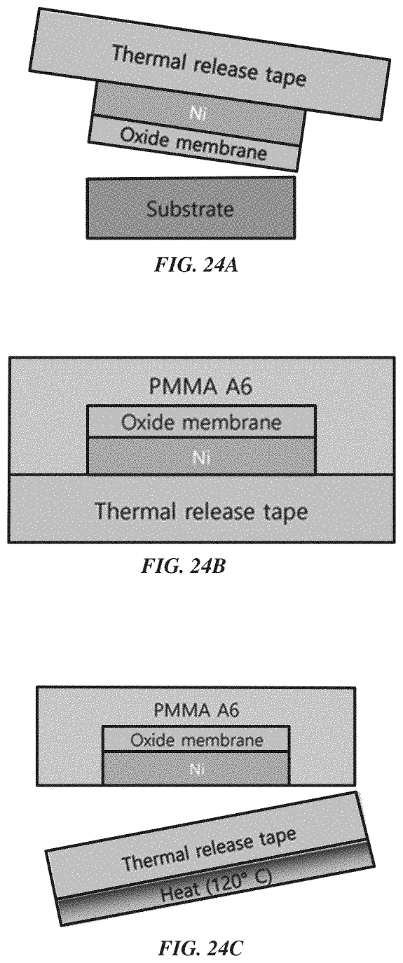

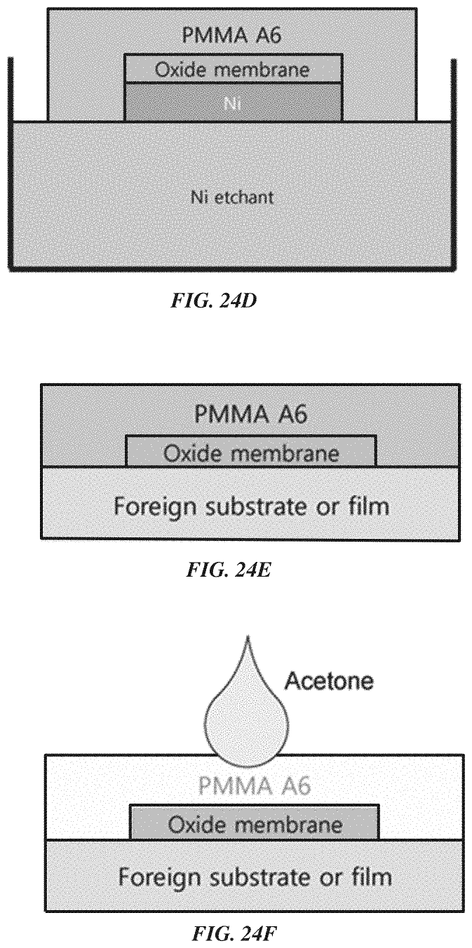

Next, heterostructures were fabricated by stacking the freestanding membranes where robust mechanical coupling was observed with high transfer yield (>90%). CFO membranes were first chosen to stack onto PMN-PT membranes (FIGS. 24A-24F) to create a composite multiferroic (FIG. 7A). This composite allowed (1) strain-mediated electric-field control of the magnetism in CFO or (2) magnetic-field induced voltage generation across PMN-PT by virtue of the magnetostrictive and piezoelectric properties of CFO and PMN-PT, respectively. It can be expected that the piezoelectric and magnetostrictive properties of these two films would be enhanced when both membranes are in their freestanding form since they are free from the substrate clamping effect. PMN-PT is a material with remarkably high piezoelectric coefficient in its single-crystalline form, while CFO has a high magnetostriction coefficient. Thus, an enhanced strain-mediated ME response would be expected from the stacked multiferroic heterostructure if both films are freestanding compared to when at least one of the films is clamped to the substrate. Until now, it was only possible to use bulk materials bonded by glue or to grow polycrystalline films on top of piezoelectric wafers for realizing such a hybrid structure. A substantially enhanced coupling effect was observed when both the CFO and PMN-PT were freestanding compared to that of the device where the PMN-PT was clamped to the substrate, by measuring the magnetically induced ME coupling as shown in FIG. 7B. As shown in FIG. 7C, the freestanding CFO/PMN-PT device produced substantially larger voltage (δVME) than the clamped device by more than an order of magnitude, with corresponding ME coupling coefficient of 477 and 2675 mV cm⁻¹ Oe⁻¹ for the clamped and declamped device, respectively. This ME coupling coefficient was approximately an order of magnitude larger than previously reported coefficients on the same material system and comparable thickness. This data indicated that strain transfer from CFO to PMN-PT was more effective for the freestanding CFO/PMN-PT heterostructure. Such excellent strain transfer between the two freestanding membranes was observed by in-situ TEM (FIG. 7D and FIGS. 17A-17B), and showed the change in the CFO structure in response to an applied voltage (−10 to 10 V) across the PMN-PT. A bonding oxide layer was spontaneously formed between the CFO membrane and Pt layer for efficient strain transfer from the PMN-PT to the CFO (FIG. 7D). FIG. 7E shows the motion of the strain fringes in CFO in response to the strain induced by the biased PMN-PT underneath (FIG. 7E). Careful steps were taken to prevent strain fringes from being generated due to the sample flexing. The excellent strain transfer from freestanding PMN-PT to CFO was also verified by observing large modulation of the magnetic hysteresis of CFO as a function of bias across PMN-PT, in contrast to the clamped device (FIGS. 18A-18B). Thus, the CFO/PMN-PT device showcased an example of a 3D heterostructure where the functionality of each material was enhanced by stacking freestanding 3D membranes of the constituent materials.

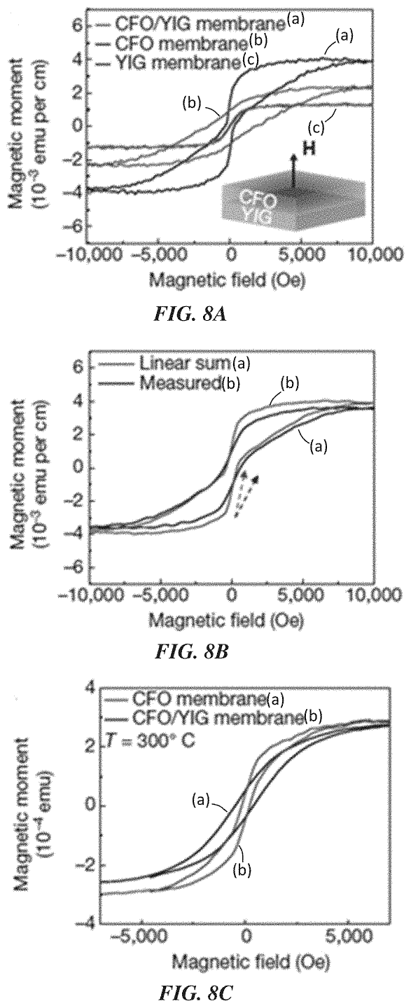

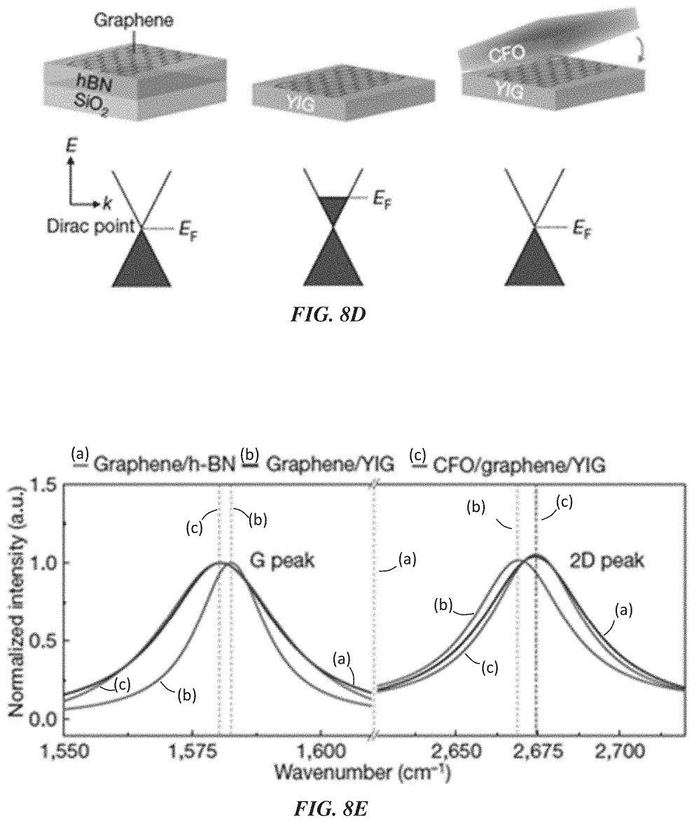

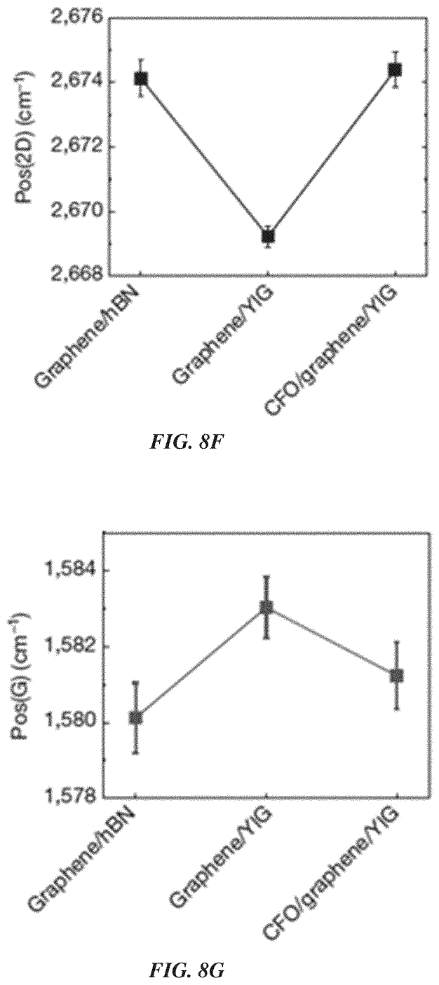

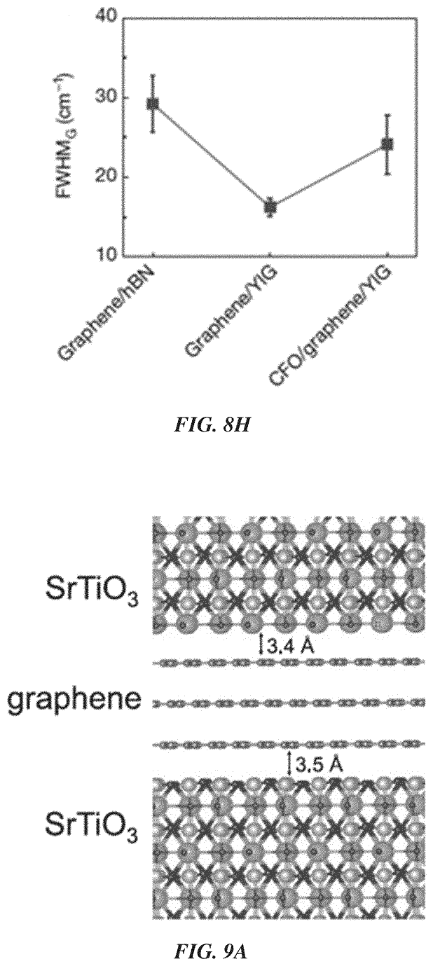

Additional 3D complex-oxide heterostructures were fabricated as well as 2D-3D mixed heterostructures forming direct junctions to study the feasibility of new physical couplings that were not possible by conventional epitaxy. First, clear magnetostatic coupling from a CFO/YIG stack was observed. As shown in FIGS. 8A-8B, the measured hysteresis of the CFO/YIG heterostructure repeatedly showed a sharper reversal of its out-of-plane magnetization compared to the sum of the individual CFO and YIG loops. A signature of magnetoelastic coupling was also observed by heating the CFO/YIG heterostructure to 300° C., just above the Curie temperature of YIG (277° C.). As shown in FIG. 8C, the loop of YIG/CFO differed from that of a single CFO layer at 300° C. although the YIG no longer contributed a magnetic moment above its Curie temperature. It was speculated that the higher thermal expansion coefficient of YIG imposed an in-plane strain on CFO resulting in a magnetoelastic anisotropy favoring out-of-plane magnetization. Cooling to room temperature restored the two-step loop seen in FIG. 8A. These findings laid the foundation to discover new physical coupling phenomena through simple stacking of these and many other functional oxides, choosing hetero-systems of interest from the huge library of freestanding membrane material sets enabled by various techniques.

This 3D heterostructuring technique not only offered great flexibility to design coupled multifunctional oxide films with enhanced performance, but also provided a platform to integrate various 3D and 2D material heterostructures with tailored functionalities to study novel interface phenomena. For example, the Fermi level of graphene was tuned with respect to its Dirac point by sandwiching it between YIG and CFO membranes. This was measured by tracking the 2D and G-peak of the Raman spectra of graphene, wherein contact with the YIG n-doped the graphene and contact with CFO p-doped the graphene, while graphene stayed intrinsic when on thick h-BN (30 nm) (FIG. 8D). It is widely known that the shift in the 2D and G-peaks as well as the full width at half maximum (FWHM) change in the G-peak correlates with the Fermi level. A clear indication of n-doping was observed on graphene transferred onto a YIG membrane relative to the undoped graphene on h-BN (blue-shift and red-shift of the 2D and G-peaks, respectively, with a narrowing of the G-peak FWHM). When graphene was sandwiched by transferring a CFO membrane on top of the graphene/YIG stack, graphene was reverted back to a nearly undoped state similar to graphene on h-BN (FIGS. 8E-8H). Such electrically coupled 2D-3D mixed heterostructures opened up a new platform to study novel interfacial and proximity induced physical couplings in 2D-3D heterostructures, which so far has been only possible theoretically. Combined with other conventional lift-off methods, this made it possible to couple and integrate an unprecedentedly broad range of functional single-crystalline membranes (III-V, III-N, complex-oxides, and 2D layered materials) on a single platform.

### Methods

### Epitaxial Graphene Growth

Monolayer epitaxial graphene (EG) was grown via silicon sublimation from the silicon face of 6H silicon carbide (SiC (0001)) in a three-phase, hot-zone, graphite furnace (Thermal Technology LLC). In this case, a 4-inch wafer was used, and a graphite crucible was constructed to accommodate the 4-inch wafer in the furnace. The SiC was first cleaned using organic solvents (acetone, isopropyl alcohol, Nanostrip™). Subsequently, the SiC is annealed in 10% hydrogen (balance argon) at 1500° C. for 30 minutes to remove subsurface damage due to chemical and mechanical polishing. The H₂ was then purged from the system, and the temperature was increased to 1800° C. for 10 minutes at 700 Torr to form the graphene layers. This process yielded low-defect density monolayer EG.

### Epitaxial Complex-Oxide Growth

### Surface Preparation

Prior to graphene transfer and growth, the STO substrate surface was dipped in buffered hydrofluoric acid for 20 seconds and annealed in a furnace at 1100° C. for 6 hours. AFM was measured to ensure step-and-terrace surface morphology. MAO and GGG substrates were rinsed in acetone and isopropyl alcohol for 5 minutes each in an ultrasonic bath with no special surface treatment.

### Pulsed Laser Deposition

STO, CFO, and YIG films were grown using a PLD with a KrF laser energy of 400 mJ and pulse rate of 10 Hz. Commercial ceramic or bulk single crystal targets were used. STO was grown on top of graphene-coated (100) STO substrates at a temperature of 850° C. and an oxygen flow of 20 mTorr. The initial 500 shots to the target were made without oxygen flow to protect the graphene layer on the oxide substrate for all materials. The CFO film was grown at a temperature of 400° C. and an oxygen pressure of 10 mTorr on top of a graphene-coated (100) MAO substrate. Finally, the YIG film was grown at a temperature of 700° C. and oxygen pressure of 20 mTorr on top of a graphene-coated (111) GGG substrate. After growth, the YIG film was then post-annealed at 850° C. for 2 hours under an oxygen ambient to improve crystal quality.

### Sputtering Deposition

90° off-axis sputtering and misaligned parallel dual planar magnetron sputtering were employed to deposit epitaxial SRO and PMN-PT films, respectively. The SRO layer (100 nm) was deposited at a temperature of 600° C. and total pressure of 200 mTorr while maintaining a 3:2 ratio of Ar and O₂ gases. The PMN-PT layer (500 nm) was grown at a temperature of 625° C. under a total background pressure of 500 mTorr, maintaining a 17:3 ratio of Ar and O₂.

### MBE Deposition

BTO films were grown by MBE in a Veeco GEN10 MBE system. Molecular beams of barium and titanium were generated using a conventional effusion cell and a Ti-Ball titanium sublimation pump, respectively. The fluxes were calibrated using reflection high-energy electron diffraction (RHEED) intensity oscillations. Barium and titanium were co-deposited onto the substrate in an oxygen background partial pressure of 7×10⁻⁷ Torr. The substrate temperature was held at 850° C. In situ RHEED images were consistent with the growth of smooth and epitaxial thin-film surfaces during deposition.

### Graphene Transfer

First, the graphene was exfoliated from its host SiC substrate by depositing Ni (˜500 nm) as an adhesive/support layer. This was accomplished by first depositing a thin Ni layer using e-beam evaporation (20 nm) to protect the graphene, followed by Ni sputtering at a chamber pressure of 1×10⁻³ Torr and Ar flow of 9.5 sccm. A thermal release tape (TRT, Revalpha Serial No. 319Y-4M) was then used to detach the Ni layer along with the graphene. The TRT/Ni/graphene stack was directly transferred onto the oxide substrate, and the TRT was released at a temperature of 120° C. Then, the Ni was etched in FeCl₃ solution, leaving only graphene on the oxide substrate. Finally, the sample was gently rinsed in acetone and IPA. This process was repeated to transfer two to three layers of graphene.

### Ni Stressor Deposition

The Ni stressor layer was deposited using plasma sputtering, using a commercially bought Ni target with 99.99% purity. A thin Ti adhesive layer (20-80 nm) was deposited using e-beam evaporation before depositing the Ni stressor. The Ni was sputtered at a chamber pressure of 2×10⁻³ Torr with 9.5 sccm of Ar flow, with a growth rate of approximately 2 micrometers/hour.

### Characterization

### SEM, EBSD, AFM, and Raman Measurements.

SEM and EBSD measurements were made using a ZEISS Merlin high-resolution SEM equipped with an EBSD detector. AFM measurements were carried out using a Park NX10 AFM tool in non-contact mode. Raman spectra were obtained using a Renishaw Invia Reflex Raman Confocal Microscope with a laser wavelength of 532 nm, power of 1 mW and a laser spot size of 2 micrometers.

### TEM Measurements

Cross-sectional TEM specimens were prepared by the focused ion beam (FIB, FEI Helios 660) technique. To prevent ion-beam damage and contamination caused by metal ions, the sample was passivated using electron beam assisted amorphous carbon (100 nm) before FIB. During the ion-milling process, the ion-beam energy was artificially controlled from 30 kV to 2 kV to achieve ultra-thin TEM samples. Ex-situ (S)TEM experiments were performed using JEOL 2010F and JEOL ARM 200CF (probe Cs-corrected) microscopes operated at 200 kV. Atomic-resolution STEM observations of epitaxial films were conducted using a JEOL ARM 200CF with a probe convergence angle of 20 mrad. A HAADF detector angle of 90-175 mrad and an ABF detector angle of 11-23 mrad were used. For in situ TEM experiments, a miniature CFO/PMN-PT ME coupled device was fabricated using the FIB technique. An e-beam assisted Pt electrode for metal probe contact was deposited onto the PMN-PT films, and the sample surface, including CFO and PMN-PT, was passivated by electron beam induced amorphous carbon. A FIB-cleaved specimen was connected with a metal half grid to make the electric circuit, and this miniature device was isolated by a side cutting method using ion milling with a low acceleration voltage of 5 kV. In order to remove the amorphous carbon assisted effect, the remaining amorphous carbon on the top of CFO was eliminated using a low-energy ion beam during the final milling stage. In situ TEM experiments were carried out using JEOL 2010F analytical electron microscope with an acceleration voltage of 200 kV in TEM mode equipped with a biasing holder (Nanofactory Instruments AB) functionalized by a scanning tunneling microscopy (STM) system. For electrical switching, a DC bias was applied inside a TEM between a sharp Pt—Ir tip operated by the STM function, contacting directly with the 7 nm thick Pt layer. The TEM probe tip placement was made far from the observed CFO region (˜5 μm), with a relatively thick platinum contact region to minimize any affects from bending of the sample. Only negligible displacement of the sample was observed during in-situ measurements, which also preclude any bending effects. Real-time HRTEM movies were captured using a 2K×2K resolution CCD camera.

### Magnetoelectric Device Fabrication

Freestanding single-crystalline PMN-PT was transferred onto a Ti-coated polydimethylsiloxane (PDMS) substrate where Ti was used as the bottom electrode, followed by fabricating a 7-nm Pt top contact on the PMN-PT. Then, the CFO membrane was directly transferred onto the Pt-coated PMN-PT to complete the heterostructured device. The device was annealed at 150° C. overnight to remove any moisture.

### Magnetoelectric Coupling Measurement

A small AC magnetic field at a frequency of 1 kHz was applied on top of a DC magnetic field (5 kOe) in-plane across the CFO/PMN-PT device, then the induced voltage was measured across the PMN-PT membrane. Voltage was generated across the PMN-PT membrane when the magnetoelastic strain in the CFO induced by the magnetic field was transferred to the PMN-PT45.

### Section I. Graphene Transfer Process

1. Epitaxial graphene grown on SiC was cleaved into a 9×9 mm² piece. (See FIG. 19A.)

2. Ni was deposited on top. First, e-beam nickel was deposited at a base pressure of 1×10⁻⁶ Torr with a thickness of 20 nm. Without breaking vacuum, Ni was sputtered at a pressure of 1.7×10⁻³ Torr in an Ar ambient (6 sccm) for 20 minutes. (See FIG. 19B.)

3. Thermal release tape (TRT) was gently placed on top, using a Q-tip to ensure no air bubbles were formed. Here the thermal release tape was around 11×11 mm². (See FIG. 19C.)

4. A tweezer was used to gently pull the TRT upwards to ensure the Ni did not crack. The Ni/gr was exfoliated from the SiC substrate at this stage. A multimeter was used to check that the entire graphene film was exfoliated by checking the conductance (which should read infinite resistance). The TRT/Ni/gr film was placed on the oxide substrate. Once again, a Q-tip was used to ensure no air bubbles were formed. (See FIG. 19D.)

5. The TRT/Ni/gr/oxide substrate was placed on a hot plate set at 120° C. for approximately 5 minutes. The entire TRT became opaque, indicating it had lost its stickiness. The TRT was discarded at this point. (See FIG. 19E.)

6. The sample was placed in a plasma chamber (150 mTorr O₂ ambient for 5 minutes) to remove any remaining TRT residue on top of the Ni, which could be redeposited on the sample during the Ni etch. (See FIG. 19F.)

7. The Ni was etched in ferric chloride (FeCl₃, MG Chemicals #415-1L). The sample could be dipped inside a beaker containing FeCl₃ (5 minutes) or FeCl₃ could be dripped on top of the Ni using a pipette. Once all traces of Ni were visibly gone, the sample was gently agitated in fresh FeCl₃ followed by DI water without allowing the surface to dry to prevent any redeposition of Ni residues. (See FIG. 19G.)

8. The sample was finally rinsed in warm Acetone (20 minutes) and IPA (5 minutes), then loaded into the epitaxial chamber for growth. (See FIG. 19H.)

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A single crystalline, freestanding layer having a thickness of less than 100 micrometers, wherein the layer is magnetostrictive or piezoelectric.

2. (canceled)

3. A multi-layer stack, comprising:
an optional substrate;
a piezoelectric layer; and
a magnetostrictive layer;
wherein:
the thickness of the multi-layer stack, including the optional substrate when present, is less than 1 millimeter; and
the distance between the piezoelectric layer and the magnetostrictive layer, as measured through the thickness of the multi-layer stack, is less than 100 micrometers.

4. The multi-layer stack of claim 3, wherein the piezoelectric layer is between the substrate and the magnetostrictive layer.

5. The multi-layer stack of claim 3, wherein the magnetostrictive layer is between the substrate and piezoelectric layer.

6. The multi-layer stack of claim 3, wherein the substrate has a Young's modulus, as measured by ASTM test E111, of less than 100 MPa.

7. The multi-layer stack of claim 3, wherein the multi-layer stack has a Young's modulus, as measured by ASTM test E111, of less than 900 GPa.

8. The multi-layer stack of claim 3, wherein the distance between the piezoelectric layer and the magnetostrictive layer, as measured through the thickness of the multi-layer stack, is less than 10 micrometers.

9. The multi-layer stack of claim 3, wherein the thickness of the multi-layer stack is less than 500 micrometers.

10. The multi-layer stack of claim 3, wherein the multi-layer stack is a freestanding multi-layer stack.

11. The multi-layer stack of claim 3, wherein the piezoelectric layer has a thickness of less than 100 micrometers.

12. The multi-layer stack of claim 3, wherein the magnetostrictive layer has a thickness of less than 100 micrometers.

13. The multi-layer stack of claim 3, wherein the magnetostrictive layer comprises a metal oxide having a perovskite, spinel, and/or garnet crystal structure.

14. The multi-layer stack of claim 3, wherein the piezoelectric layer comprises a metal oxide having a perovskite, spinel, and/or garnet crystal structure.

15. The multi-layer stack of claim 3, wherein the piezoelectric layer has at least one lateral dimension of at least 1 micrometer.

16. The multi-layer stack of claim 3, wherein the magnetostrictive layer has at least one lateral dimension of at least 1 micrometer.

17. A method, comprising:
forming a single crystalline layer directly on a single crystalline growth substrate; and
separating the single crystalline layer from the single crystalline growth substrate;
wherein the lattice mismatch between the single crystalline growth substrate and the single crystalline layer is at least 2%.

18. The method of claim 17, wherein the single crystalline layer has a perovskite crystal structure and the single crystalline growth substrate has a perovskite crystal structure.

19. The method of claim 17, wherein the single crystalline layer has a spinel crystal structure and the single crystalline growth substrate has a spinel crystal structure.

20. The method of claim 17, wherein the single crystalline layer has a garnet crystal structure and the single crystalline growth substrate has a garnet crystal structure.

21. The method of claim 17, wherein the single crystalline layer is a magnetostrictive layer.

22-26. (canceled)
